(19) United States
(12) Patent Application Publication
(10) Pub. No.: US 2026/0123037 A1
(43) Pub. Date: Apr. 30, 2026

(54) INTEGRATED CIRCUIT DEVICE WITH IMPROVED CONTACT DESIGN

(71) Applicant: SAMSUNG ELECTRONICS CO., LTD., Suwon-si (KR)

(72) Inventors: Hyewon JEONG, Suwon-si (KR); Geunwoo Kim, Suwon-si (KR); Wandon Kim, Suwon-si (KR); Sungyu Choi, Suwon-si (KR); Mingyu Kim, Suwon-si (KR); Sanghoon Jeong, Suwon0si (KR)

(73) Assignee: SAMSUNG ELECTRONICS CO., LTD., Suwon-si (KR)

(21) Appl. No.: 19/190,232

(22) Filed: Apr. 25, 2025

(30) Foreign Application Priority Data
Oct. 29, 2024 (KR) 10-2024-0149773

(51) Int. Cl. H10D 84/83; H10D 30/00; H10D 30/01; H10D 30/43; H10D 30/69; H10D 62/10; H10D 62/13; H10D 62/83; H10D 62/832; H10D 64/23; H10D 64/62; H10D 84/01

(52) U.S. Cl. CPC H10D 84/832; H10D 30/43; H10D 30/502; H10D 30/794; H10D 62/121; H10D 62/151; H10D 62/83; H10D 62/832; H10D 64/256; H10D 64/62; H10D 84/8312; H10D 30/014; H10D 30/0191; H10D 84/0149

(57) ABSTRACT

Provided is an integrated circuit device including: first and second transistors including first and second channel regions and first and second source/drain regions respectively connected to the first and second channel regions; and first and second contact structures respectively connected to the first and second source/drain regions; wherein each of the first and second contact structures includes at least two metal-containing films, wherein the first contact structure includes a first major metal plug having a largest volume among volumes of the at least two metal-containing films of the first contact structure, wherein the second contact structure includes a second major metal plug having a largest volume among volumes of the at least two metal-containing films of the second contact structure, wherein the first and second major metal plugs respectively include different metals, and wherein the first and second major metal plugs have different cross-sectional shapes.

### CROSS-REFERENCE TO RELATED APPLICATION

This application claims priority to Korean Patent Application No. 10-2024-0149773, filed in the Korean Intellectual Property Office on Oct. 29, 2024, the disclosure of which is incorporated herein by reference in its entirety.

### BACKGROUND

The disclosure relates to an integrated circuit device, and more particularly, to an integrated circuit device including a metal wiring layer.

Due to the advance of electronics technology, integrated circuit devices have been rapidly down-scaled, and the line widths and pitches of metal wiring layers in integrated circuit devices also have been refined. Therefore, there is a need to develop integrated circuit devices that have metal wiring structures capable of suppressing an increase in resistance of metal wiring layers and improving the electrical characteristics and reliability thereof.

### SUMMARY

Provided is an integrated circuit device that includes a contact structure capable of improving the performance and reliability of a transistor by increasing carrier mobility and reducing contact resistance according to a channel type of the transistor.

According to an aspect of the disclosure, an integrated circuit device includes: a first transistor including a first channel region and a first source/drain region connected to the first channel region; a second transistor including a second channel region and a second source/drain region connected to the second channel region; a first contact structure connected to the first source/drain region; and a second contact structure connected to the second source/drain region, wherein each of the first contact structure and the second contact structure includes at least two metal-containing films, wherein the first contact structure includes a first major metal plug having a largest volume among respective volumes of each of the at least two metal-containing films of the first contact structure, wherein the second contact structure includes a second major metal plug having a largest volume among respective volumes of each of the at least two metal-containing films of the second contact structure, wherein the first major metal plug and the second major metal plug respectively include different metals, and wherein a cross-sectional shape of the first major metal plug is different from a cross-sectional shape of the second major metal plug.

According to an aspect of the disclosure, an integrated circuit device includes: a plurality of channel regions each including a plurality of nanosheets, the plurality of channel regions including a first channel region and a second channel region; a plurality of gate lines each surrounding a channel region of the plurality of channel regions; a first source/drain region in contact with the plurality of nanosheets of the first channel region, the first source/drain region including a Si layer doped with an n-type dopant; a first contact structure connected to the first source/drain region; a second source/drain region in contact with the plurality of nanosheets of the second channel region, the second source/drain region including a SiGe layer doped with a p-type dopant; and a second contact structure connected to the second source/drain region, wherein each of the first contact structure and the second contact structure includes at least two metal-containing films, wherein the first contact structure includes a first major metal plug having a largest volume among respective volumes of each of the at least two metal-containing films of the first contact structure, wherein the second contact structure includes a second major metal plug having a largest volume among respective volumes of each of the at least two metal-containing films of the second contact structure, wherein the first major metal plug and the second major metal plug respectively include different metals, and wherein a cross-sectional shape of the first major metal plug is different from a cross-sectional shape of the second major metal plug.

According to an aspect of the disclosure, an integrated circuit device includes: a plurality of channel regions each including a plurality of nanosheets, the plurality of channel regions including a first channel region and a second channel region; an n-channel metal-oxide semiconductor (NMOS) transistor including: the first channel region; a first gate line surrounding the plurality of nanosheets of the first channel region; and a first source/drain region in contact with the plurality of nanosheets of the first channel region, the first source/drain region including a Si layer doped with an n-type dopant; a p-channel metal-oxide semiconductor (PMOS) transistor including: the second channel region; a second gate line surrounding the plurality of nanosheets of the second channel region; and a second source/drain region in contact with the plurality of nanosheets of the second channel region, the second source/drain region including a SiGe layer doped with a p-type dopant; a first contact structure connected to the first source/drain region; and a second contact structure connected to the second source/drain region, wherein each of the first contact structure and the second contact structure includes at least two metal-containing films, wherein the first contact structure includes a first major metal plug having a largest volume among respective volumes of the at least two metal-containing films of the first contact structure, wherein the second contact structure includes a second major metal plug having a largest volume among respective volumes of the at least two metal-containing films of the second contact structure, wherein the first major metal plug and the second major metal plug respectively include different metals selected from molybdenum (Mo), copper (Cu), tungsten (W), cobalt (Co), ruthenium (Ru), manganese (Mn), titanium (Ti), tantalum (Ta), and aluminum (Al), and wherein a cross-sectional shape of the first major metal plug is different from a cross-sectional shape of the second major metal plug.

### BRIEF DESCRIPTION OF DRAWINGS

The above and other aspects and features of certain embodiments of the present disclosure will be more apparent from the following description taken in conjunction with the accompanying drawings, in which:

FIG. 1 is a cross-sectional view illustrating an integrated circuit device according to one or more embodiments;

FIG. 2 is an enlarged cross-sectional view illustrating regions EX1 and EX2 of FIG. 1;

FIGS. 3, 4, 5, 6, 7, 8, 9 and 10 are cross-sectional views respectively illustrating integrated circuit devices according to one or more embodiments;

FIGS. 11A, 11B, 11C, 11D, 11E, 11F, 11G and 11H are cross-sectional views respectively illustrating a sequence of processes of a method of fabricating an integrated circuit device, according to one or more embodiments;

FIGS. 12A, 12B, 12C, 12D and 12E are enlarged cross-sectional views respectively illustrating, in more detail, a sequence of processes of a method of fabricating an integrated circuit device, according to one or more embodiments;

FIGS. 13A and 13B are cross-sectional views respectively illustrating a sequence of processes of a method of fabricating an integrated circuit device, according to one or more embodiments;

FIGS. 14A, 14B, 14C, 14D and 14E are cross-sectional views respectively illustrating a sequence of processes of a method of fabricating an integrated circuit device, according to one or more embodiments; and

FIGS. 15A, 15B, 15C and 15D are cross-sectional views respectively illustrating a sequence of processes of a method of fabricating an integrated circuit device, according to one or more embodiments.

### DETAILED DESCRIPTION

Hereinafter, embodiments of the disclosure will be described in detail with reference to the accompanying drawings. Like components are denoted by like reference numerals throughout the specification, and repeated descriptions thereof are omitted.

When an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, each step or operation may be implemented in an order different from the illustrated order unless the context clearly indicates otherwise. One or more steps or operations may be omitted unless the context of the disclosure clearly indicates otherwise.

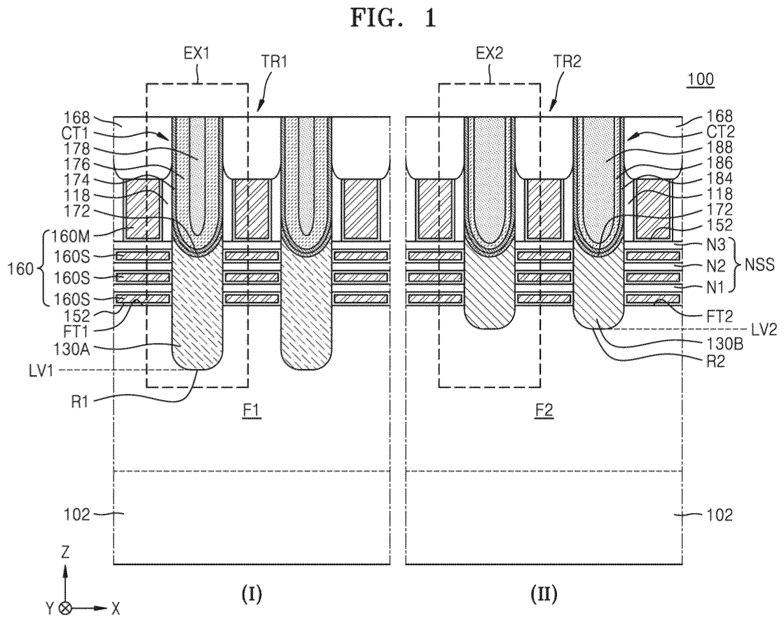

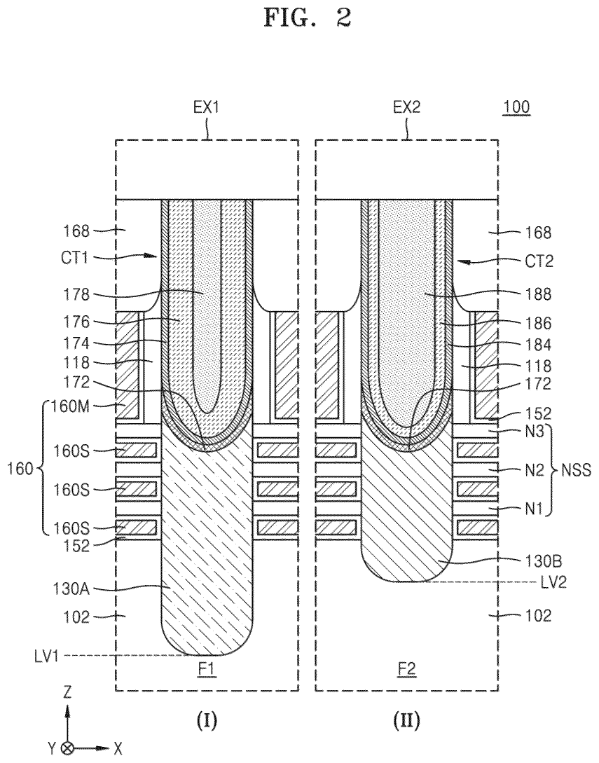

FIG. 1 is a cross-sectional view illustrating an integrated circuit device 100 according to one or more embodiments. FIG. 2 is an enlarged cross-sectional view illustrating regions EX1 and EX2 of FIG. 1.

Referring to FIGS. 1 and 2, the integrated circuit device 100 includes a substrate 102 having a first device area I and a second device area II. The first device area I and the second device area II of the substrate 102 respectively refer to different areas of the substrate 102 and may respectively include areas for performing different operations in the substrate 102. The first device area I and the second device area II may be separate from each other or may be located adjacent to, and to be connected to, each other.

The first device area I and the second device area II may respectively require different threshold voltages. For example, the first device area I may include an n-channel metal-oxide semiconductor (NMOS) transistor area, and the second device area II may include a p-channel metal-oxide semiconductor (PMOS) transistor area.

In one or more embodiments, each of the first device area I and the second device area II may include an area selected from a memory area and a non-memory area. The memory area may constitute a volatile memory device, such as dynamic random access memory (DRAM) or static RAM (SRAM), or a non-volatile memory device, such as read-only memory (ROM), mask ROM (MROM), programmable ROM (PROM), erasable ROM (EPROM), electrically erasable ROM (EEPROM), ferromagnetic RAM (FRAM), phase-change RAM (PRAM), magnetic RAM (MRAM), resistive RAM (RRAM), or flash memory. The non-memory area may include a logic area. The logic area may include standard cells for performing logical functions, such as a counter and a buffer. The standard cells may include various logic cells including a plurality of circuit elements, such as a transistor and a register. The logic cells may each constitute, for example, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slaver flip-flop, a latch, or the like.

The integrated circuit device 100 including field-effect transistors, which each have a gate-all-around structure including a nanowire or nanosheet-shaped active region and a gate surrounding the active region, is described with reference to FIGS. 1 and 2.

Referring to FIGS. 1 and 2, the substrate 102 may include a semiconductor, such as Si or Ge, or a compound semiconductor, such as SiGe, SiC, GaAs, InAs, InGaAs, or InP. As used herein, each of the terms “SiGe”, “SiC”, “GaAs”, “InAs”, “InGaAs”, and “InP” refers to a material including elements contained in each term and is not a chemical formula representing a stoichiometric relationship. The substrate 102 may include a conductive region, for example, an impurity-doped well or an impurity-doped structure.

A first fin-type active region F1 may protrude in a vertical direction (a Z direction) from the substrate 102 in the first device area I, and a second fin-type active region F2 may protrude in the vertical direction (the Z direction) from the substrate 102 in the second device area II. The first and second fin-type active regions F1 and F2 may extend in a first horizontal direction (an X direction) to be parallel to each other. The first fin-type active region F1 may have a first fin top surface FT1, and the second fin-type active region F2 may have a second fin top surface FT2. The first fin-type active region F1 may be defined by a device isolation trench formed in the substrate 102 in the first device area I, and the second fin-type active region F2 may be defined by a device isolation trench formed in the substrate 102 in the second device area II. A specific example of a constituent material of each of the first and second fin-type active regions F1 and F2 may be the same as the constituent material of the substrate 102 described above.

A plurality of gate lines 160 extend lengthwise in a second horizontal direction (a Y direction) over the first and second fin-type active regions F1 and F2, the second horizontal direction (the Y direction) intersecting with the first horizontal direction (the X direction). Each of the first horizontal direction (the X direction) and the second horizontal direction (the Y direction) may be orthogonal to the vertical direction (the Z direction). The number of gate lines 160 arranged over the first and second fin-type active regions F1 and F2 is not particularly limited. For example, at least two gate lines 160 may be arranged over each of the first and second fin-type active regions F1 and F2.

Each of the plurality of gate lines 160 may extend lengthwise in the second horizontal direction (the Y direction) over the first and second fin-type active regions F1 and F2, the second horizontal direction (the Y direction) intersecting with the first horizontal direction (the X direction). In regions in which the first and second fin-type active regions F1 and F2 intersect the plurality of gate lines 160, a plurality of nanosheet stacks NSS may be arranged over each of the respective first and second fin top surfaces FT1 and FT2 of the first and second fin-type active regions F1 and F2. Each of the plurality of nanosheet stacks NSS may constitute a channel region. Each of the plurality of nanosheet stacks NSS may be located apart (i.e., separated) from each of the first and second fin-type active regions F1 and F2 in the vertical direction (the Z direction) to face each of the first and second fin top surfaces FT1 and FT2.

Each of the plurality of nanosheet stacks NSS may include first to third nanosheets N1, N2, and N3 overlapping each other in the vertical direction (the Z direction) over each of the respective first and second fin top surfaces FT1 and FT2 of the first and second fin-type active regions F1 and F2. As used herein, the term “nanosheet” refers to a conductive structure having a cross-section that is substantially perpendicular to a current-flowing direction. The nanosheet may also be understood as including a nanowire. The first to third nanosheets N1, N2, and N3 may respectively have different vertical distances (Z-direction distances) from each of the first and second fin top surfaces FT1 and FT2.

The respective numbers of nanosheet stacks NSS and gate lines 160, which are arranged over each of the first and second fin-type active regions F1 and F2 are not particularly limited. For example, one nanosheet stack NSS or a plurality of nanosheet stacks NSS and one gate line 160 or a plurality of gate lines 160 may be arranged over one fin-type active region F1 or F2.

Although FIGS. 1 and 2 illustrate an example in which each of the plurality of nanosheet stacks NSS includes three nanosheets including the first to third nanosheets N1, N2, and N3, the number of nanosheets in the nanosheet stack NSS is not particularly limited. For example, each of the plurality of nanosheet stacks NSS may include one nanosheet, two nanosheets, or four or more nanosheets.

Each of the first to third nanosheets N1, N2, and N3 may have a channel region. Each of the first to third nanosheets N1, N2, and N3, which are included in the nanosheet stack NSS, may have a channel region. In one or more embodiments, each of the first to third nanosheets N1, N2, and N3 in the nanosheet stack NSS may include a Si layer, a SiGe layer, or a combination thereof. In one or more embodiments, the first to third nanosheets N1, N2, and N3 may have a substantially equal thickness in the vertical direction (the Z direction). In one or more embodiments, at least some of the first to third nanosheets N1, N2, and N3 may respectively have different thicknesses in the vertical direction (the Z direction).

In one or more embodiments, in the first device area I and the second device area II, the first to third nanosheets N1, N2, and N3 in one nanosheet stack NSS may each have an equal size in the first horizontal direction (the X direction). In one or more embodiments, at least some of the first to third nanosheets N1, N2, and N3 in one nanosheet stack NSS may respectively have different sizes in the first horizontal direction (the X direction). For example, in the first horizontal direction (the X direction), the length of the first nanosheet N1 closest to each of the first and second fin top surfaces FT1 and FT2, among the first to third nanosheets N1, N2, and N3, may be less or greater than the length of the third nanosheet N3 farthest from each of the first and second fin top surfaces FT1 and FT2.

In the first device area I, a plurality of first recesses R1 may be formed in the first fin-type active region F1. In the second device area II, a plurality of second recesses R2 may be formed in the second fin-type active region F2. A vertical level LV1 of the lowermost surface of each of the plurality of first recesses R1 and a vertical level LV2 of the lowermost surface of each of the plurality of second recesses R2 may be lower than vertical levels of the respective first and second fin top surfaces FT1 and FT2 of the first and second fin-type active regions F1 and F2, respectively. The vertical level LV1 of the lowermost surface of each of the plurality of first recesses R1 may be lower than the vertical level LV2 of the lowermost surface of each of the plurality of second recesses R2. As used herein, the term “vertical level” refers to a distance in the vertical direction (the Z direction or the-Z direction) from each of the respective first and second fin top surfaces FT1 and FT2 of the first and second fin-type active regions F1 and F2. For example, a vertical-direction (Z-direction) distance from the first fin top surface FT1 of the first fin-type active region F1 to the vertical level LV1 of the lowermost surface of each of the plurality of first recesses R1 may be greater than a vertical-direction (Z-direction) distance from the second fin top surface FT2 of the second fin-type active region F2 to the vertical level LV2 of the lowermost surface of each of the plurality of second recesses R2.

In the first device area I, a plurality of first source/drain regions 130A may be respectively arranged on the plurality of first recesses R1. In the second device area II, a plurality of second source/drain regions 130B may be respectively arranged on the plurality of second recesses R2.

Each of the plurality of gate lines 160 may be arranged over the first and second fin-type active regions F1 and F2 and may surround each of the first to third nanosheets N1, N2, and N3 while covering the plurality of nanosheet stacks NSS. Transistors may be respectively formed in regions in which the first and second fin-type active regions F1 and F2 intersect the gate lines 160, on the substrate 102. In one or more embodiments, the first device area I may include an NMOS transistor area, and a first transistor TR1 including an NMOS transistor may be formed in each region, in which the first fin-type active region F1 intersects the gate line 160, in the first device area I. In addition, the second device area II may include a PMOS transistor area, and a second transistor TR2 including a PMOS transistor may be formed in each region, in which the second fin-type active region F2 intersects the gate line 160, in the second device area II.

In each of the first device area I and the second device area II, the gate line 160 may include a main gate portion 160M and a plurality of sub-gate portions 160S. The main gate portion 160M may extend lengthwise in the second horizontal direction (the Y direction) to cover the upper surface of the nanosheet stack NSS. The plurality of sub-gate portions 160S may be integrally connected to the main gate portion 160M and may be respectively arranged one-by-one between each of the first to third nanosheets N1, N2, and N3 and between the first nanosheet N1 and each of the first and second fin-type active regions F1 and F2.

Each of the plurality of gate lines 160 may include a metal, a metal nitride, a metal carbide, or a combination thereof. The metal may be selected from titanium (Ti), tantalum (Ta), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from TiN and TaN. The metal carbide may include TiAlC. In one or more embodiments, the gate line 160 may have a structure in which a metal nitride film, a metal film, a conductive capping film, and a gap-fill metal film are sequentially stacked in the stated order. Each of the metal nitride film and the metal film may include at least one metal selected from Ti, Ta, W, Ru, Nb, Mo, and Hf. The gap-fill metal film may include a W film or an Al film. Each of the plurality of gate lines 160 may include at least one work function metal-containing film. The at least one work function metal-containing film may include at least one metal selected from Ti, Ta, W, Ru, Nb, Mo, Hf, Ni, Co, Pt, Yb, Tb, Dy, Er, and Pd.

In one or more embodiments, each of the plurality of gate lines 160 may include a stack structure of a plurality of metal-containing films, and among the plurality of gate lines 160, a gate line 160 arranged in the first device area I and a gate line 160 arranged in the second device area II may respectively have different stack structures. For example, the gate line 160 in the first device area I and the gate line 160 in the second device area II may respectively have different stack structures selected from a stack structure of TiAlC/TiN/W, a stack structure of TiN/TaN/TiAlC/TiN/W, and a stack structure of TiN/TaN/TiN/TialC/TiN/W, but the disclosure is not limited thereto.

In the first device area I and the second device area II, a gate dielectric film 152 may be arranged between the gate line 160 and each of the first to third nanosheets N1, N2, and N3. The gate dielectric film 152 may include portions covering respective surfaces of the first to third nanosheets N1, N2, and N3, portions covering sidewalls of the main gate portion 160M, and portions covering the respective first and second fin top surfaces FT1 and FT2 of the first and second fin-type active regions F1 and F2.

In one or more embodiments, the gate dielectric film 152 may include a high-k film. The high-k film may include a material having a dielectric constant that is greater than that of a silicon oxide film. For example, the high-k film may have a dielectric constant of about 10 to about 25. The high-k film may include, but is not limited to, hafnium oxide.

The first to third nanosheets N1, N2, and N3 may respectively include semiconductor layers including the same element. In an example, each of the first to third nanosheets N1, N2, and N3 may include a Si layer. In the first device area I, the first to third nanosheets N1, N2, and N3 may be doped with a dopant of the same conductivity type as that of the first source/drain region 130A. In the second device area II, the first to third nanosheets N1, N2, and N3 may be doped with a dopant of the same conductivity type as that of the second source/drain region 130B. For example, the first to third nanosheets N1, N2, and N3 in the first device area I may include a Si layer doped with an n-type dopant, and the first to third nanosheets N1, N2, and N3 in the second device area II may include a Si layer doped with a p-type dopant.

In the first device area I and the second device area II, the sidewalls of the gate line 160 may be respectively covered by a plurality of insulating spacers 118. In the first device area I and the second device area II, the plurality of insulating spacers 118 may include portions arranged on the top surface of the nanosheet stack NSS and respectively covering the sidewalls of the gate line 160. The plurality of insulating spacers 118 may include portions arranged on the top surface of the nanosheet stack NSS and respectively covering both sidewall of the main gate portion 160M based on the first horizontal direction (the X direction). In the plurality of insulating spacers 118, a portion covering the top surface of the nanosheet stack NSS may be separated from the gate line 160 in the first horizontal direction (the X direction) with the gate dielectric film 152 therebetween. Each of the plurality of insulating spacers 118 may include an oxide film, a nitride film, or a combination thereof. For example, each of the plurality of insulating spacers 118 may include silicon nitride (SiN), silicon oxide, SiCN, SiBN, SiON, SiOCN, SiBCN, SiOC, or a combination thereof. As used herein, each of the terms “SiN”, “SiCN”, “SiBN”, “SiON”, “SiOCN”, “SiBCN”, and “SiOC” refers to a material including elements contained in each term and is not a chemical formula representing a stoichiometric relationship.

In the first device area I and the second device area II, the plurality of first source/drain regions 130A and the plurality of second source/drain regions 130B may each include portions respectively contacting the first to third nanosheets N1, N2, and N3 and a portion contacting the gate dielectric film 152. The gate dielectric film 152 may include portions arranged between each of the first to third nanosheets N1, N2, and N3 and between the first nanosheet N1 and each of the first and second fin-type active regions F1 and F2 and vertically overlapping the first to third nanosheets N1, N2, and N3.

When the first device area I includes an NMOS transistor area and the second device area II includes a PMOS transistor area, the plurality of first source/drain regions 130A in the first device area I may each include a Si layer doped with an n-type dopant, and the plurality of second source/drain regions 130B in the second device area II may each include a SiGe layer doped with a p-type dopant. The n-type dopant may be selected from phosphorus (P), arsenic (As), and antimony (Sb). The p-type dopant may be selected from boron (B) and gallium (Ga).

Each of the plurality of first source/drain regions 130A in the first device area I and each of the plurality of second source/drain regions 130B in the second device area II may have different shapes and sizes. In one or more embodiments, the size of each of the plurality of first source/drain regions 130A in the vertical direction (the Z direction) may be greater than the size of each of the plurality of second source/drain regions 130B in the vertical direction (the Z direction). In one or more embodiments, the size of each of the plurality of second source/drain regions 130B in the second horizontal direction (the Y direction) may be greater than the size of each of the plurality of first source/drain regions 130A in the second horizontal direction (the Y direction). The plurality of first source/drain regions 130A and the plurality of second source/drain regions 130B are not limited to the shapes shown in FIGS. 1 and 2 and may have various shapes and sizes.

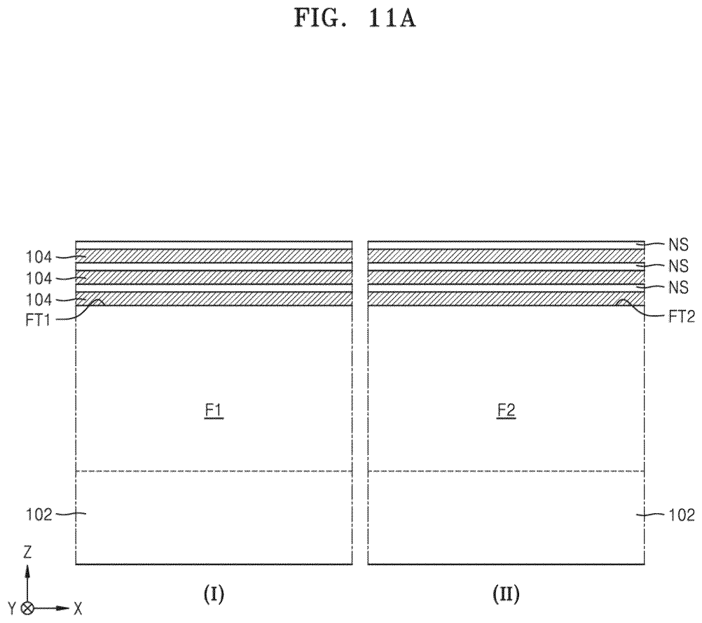

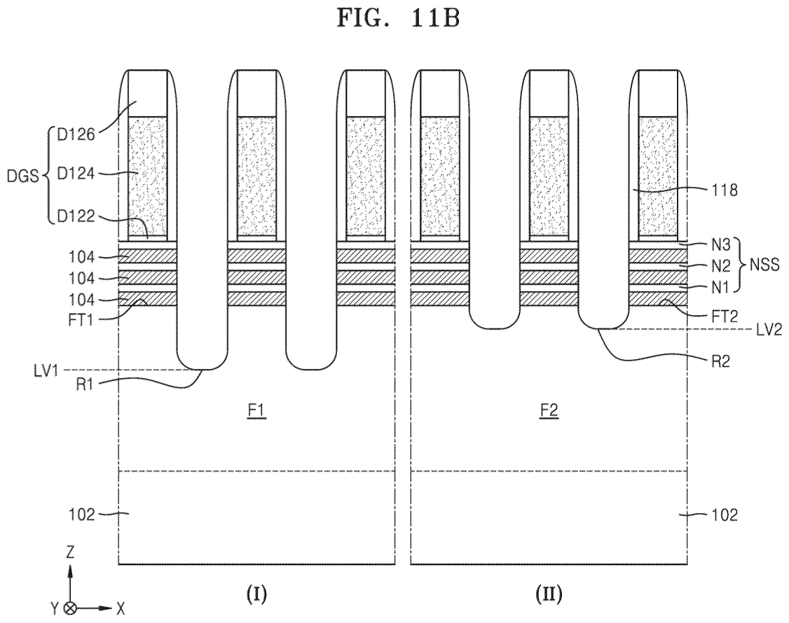

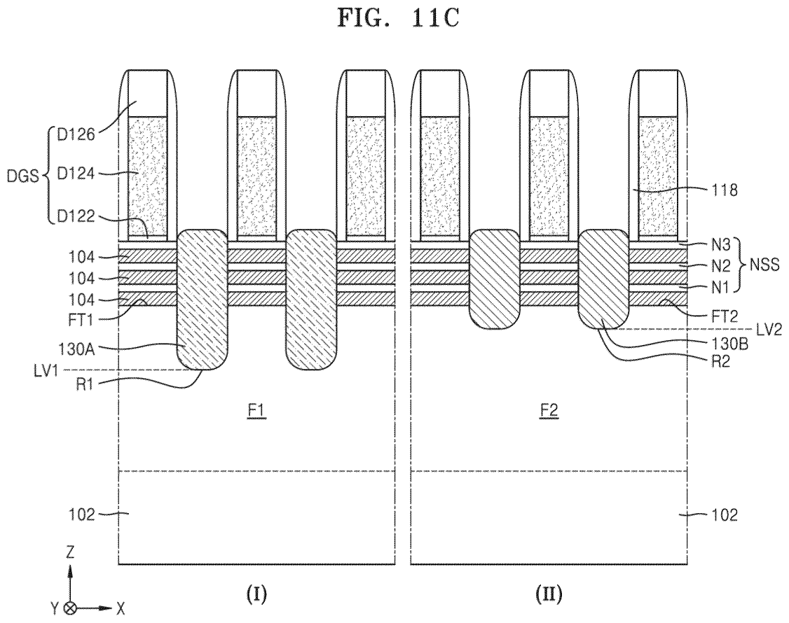

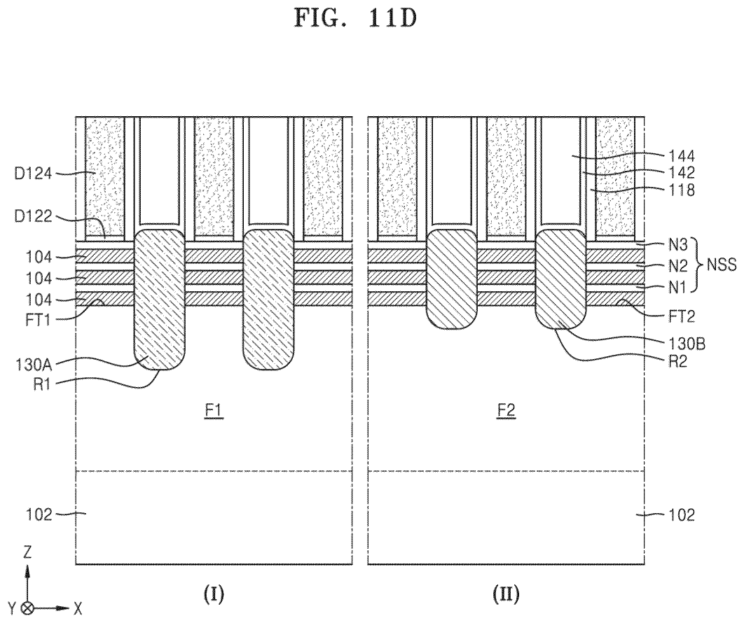

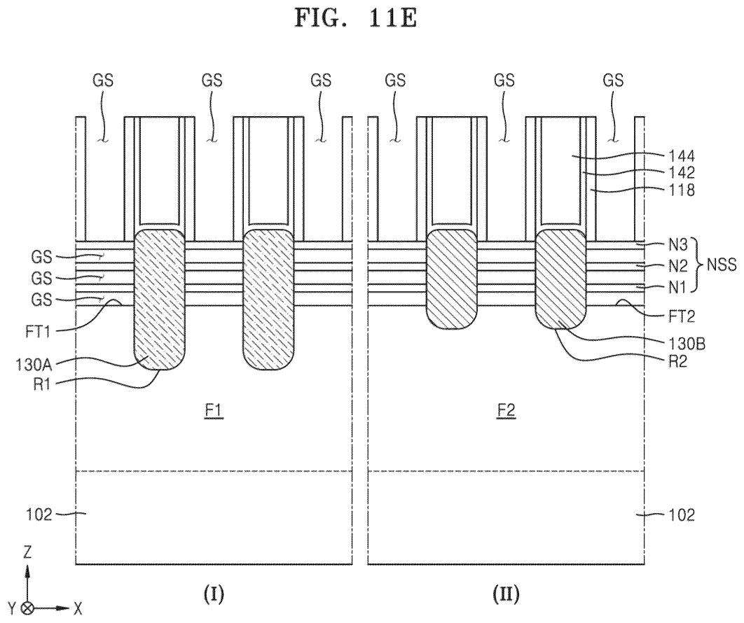

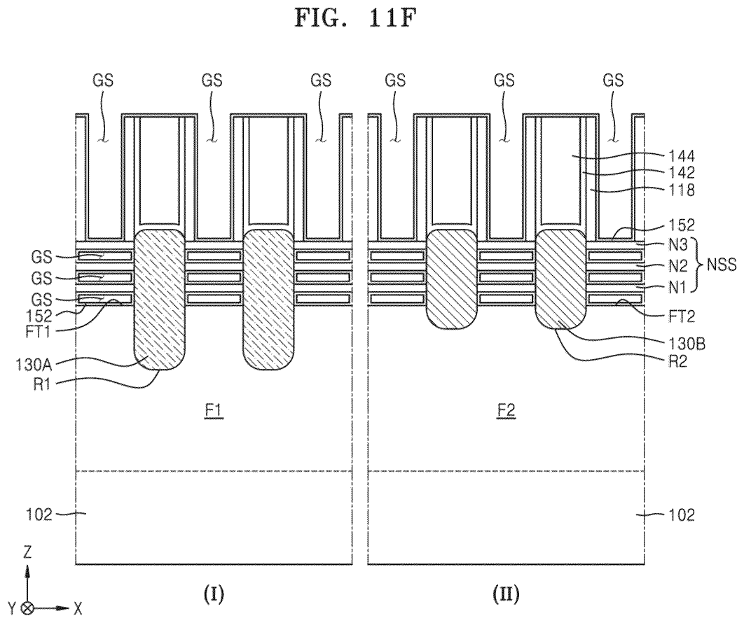

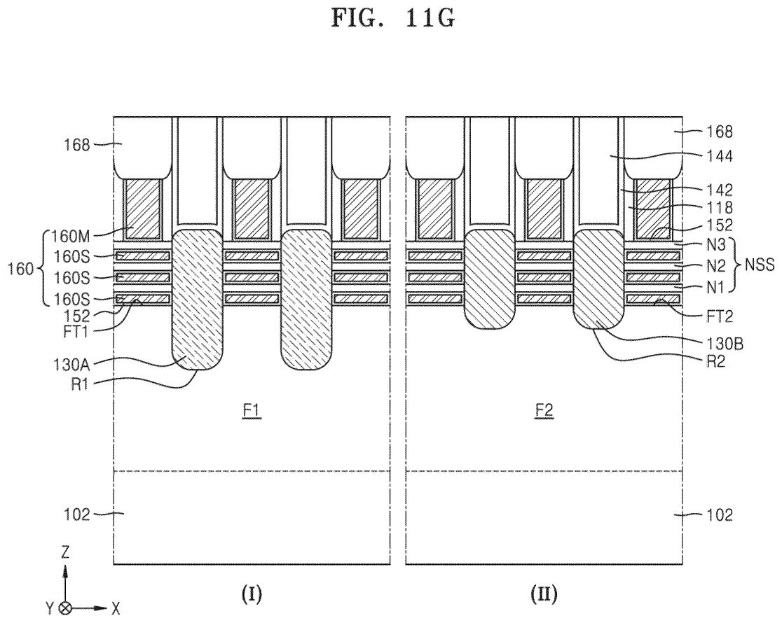

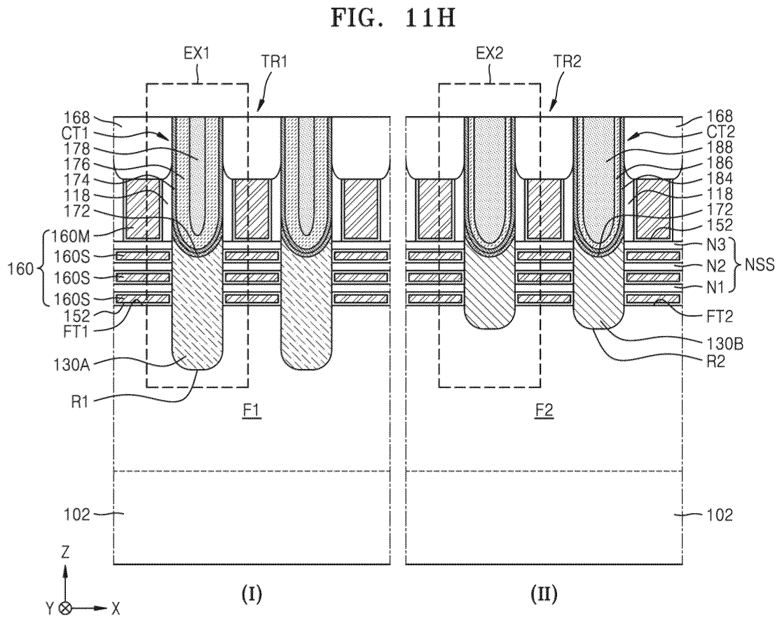

In the first device area I and the second device area II, a certain surface of each of the plurality of first source/drain regions 130A, the plurality of second source/drain regions 130B, and the plurality of insulating spacers 118 may be covered by an insulating liner 142 (see FIGS. 11D to 11G). The insulating liner 142 may be in contact with a certain surface of each of the plurality of first source/drain regions 130A and the plurality of second source/drain regions 130B and with a certain surface of the sidewall of the insulating spacer 118 and may conformally cover the surfaces thereof. The insulating liner 142 may include SiN, SiCN, SiBN, SiON, SiOCN, SiBCN, SiOC, or a combination thereof. In one or more embodiments, a constituent material of the insulating spacer 118 may be different from a constituent material of the insulating liner 142. For example, the insulating spacer 118 may include a SiOCN film, a SiON film, or a combination thereof, and the insulating liner 142 may include a SiN film.

An inter-gate dielectric 144 (see FIGS. 11D to 11G) may be arranged on the insulating liner 142. The inter-gate dielectric 144 may include a silicon nitride film, a silicon oxide film, SiON, SiOCN, or a combination thereof.

As shown in FIGS. 1 and 2, the upper surface of each of the gate dielectric film 152, the gate line 160, and the insulating spacer 118 may be covered by a capping insulating pattern 168. The capping insulating pattern 168 may include a silicon nitride film.

A metal silicide film 172 may be formed on the upper surface of each of the plurality of first source/drain regions 130A and the plurality of second source/drain regions 130B. The metal silicide film 172 may include a metal including Ti, W, Ru, Nb, Mo, Hf, Ni, Co, Pt, Yb, Tb, Dy, Er, or Pd. For example, the metal silicide film 172 may include, but is not limited to, titanium silicide.

In the first device area I, a first contact structure CT1 may be arranged over each of the plurality of first source/drain regions 130A. The first contact structure CT1 may be connected to the first source/drain region 130A via the metal silicide film 172. In the second device area II, a second contact structure CT2 may be arranged over each of the plurality of second source/drain regions 130B. The second contact structure CT2 may be connected to the second source/drain region 130B via the metal silicide film 172.

Each of the first contact structure CT1 and the second contact structure CT2 may pass through the inter-gate dielectric 144 and the insulating liner 142 (see FIGS. 11D to 11G) in the vertical direction (the Z direction) and may have an end contacting the metal silicide film 172. A plurality of first contact structures CT1 and a plurality of second contact structures CT2 may each be separate from the main gate portion 160M of the gate line 160 in the first horizontal direction (the X direction), with the insulating spacer 118 therebetween.

In the first device area I, the nanosheet stack NSS arranged over the first fin-type active region F1 and including the first to third nanosheets N1, N2, and N3, the first source/drain region 130A connected to the first to third nanosheets N1, N2, and N3, and the gate line 160 surrounding the first to third nanosheets N1, N2, and N3 may constitute a first transistor TR1. In the second device area II, the nanosheet stack NSS arranged over the second fin-type active region F2 and including the first to third nanosheets N1, N2, and N3, the second source/drain region 130B connected to the first to third nanosheets N1, N2, and N3, and the gate line 160 surrounding the first to third nanosheets N1, N2, and N3 may constitute a second transistor TR2.

Each of the first contact structure CT1 and the second contact structure CT2 may include at least two metal-containing films. More specifically, in the first device area I, the first contact structure CT1 may include a first conductive barrier metal-containing film 174, a first major metal plug 176, and a first minor metal plug 178, which are sequentially stacked in the stated order on the metal silicide film 172. In the first contact structure CT1, at least two of the first conductive barrier metal-containing film 174, the first major metal plug 176, and the first minor metal plug 178 may respectively include different metals. In the second device area II, the second contact structure CT2 may include a second conductive barrier metal-containing film 184, a second minor metal plug 186, and a second major metal plug 188, which are sequentially stacked in the stated order on the metal silicide film 172. In the second contact structure CT2, at least two of the second conductive barrier metal-containing film 184, the second minor metal plug 186, and the second major metal plug 188 may respectively include different metals.

In the first contact structure CT1 arranged in the first device area I, the first major metal plug 176 may have the largest volume, among metal-containing films of the first contact structure CT1. In one or more embodiments, in the first contact structure CT1, the volume of the first major metal plug 176 may be greater than the volume of the first minor metal plug 178, and the first major metal plug 176 and the first minor metal plug 178 may respectively include different metals.

In the second contact structure CT2 arranged in the second device area II, the second major metal plug 188 may have the largest volume, among metal-containing films of the second contact structure CT2. In one or more embodiments, in the second contact structure CT2, the volume of the second major metal plug 188 may be greater than the volume of the second minor metal plug 186, and the second major metal plug 188 and the second minor metal plug 186 may respectively include different metals.

In one or more embodiments, each of the first contact structure CT1 and the second contact structure CT2 may include molybdenum (Mo), copper (Cu), tungsten (W), cobalt (Co), ruthenium (Ru), manganese (Mn), titanium (Ti), tantalum (Ta), aluminum (Al), titanium nitride (TiN), tantalum nitride (TaN), tungsten nitride (WN), tungsten carbonitride (WCN), titanium silicon nitride (TiSiN), tantalum silicon nitride (TaSiN), tungsten silicon nitride (WSiN), or a combination thereof.

In one or more embodiments, the first major metal plug 176 of the first contact structure CT1 and the second major metal plug 188 of the second contact structure CT2 may respectively include different metals selected from molybdenum (Mo), copper (Cu), tungsten (W), cobalt (Co), ruthenium (Ru), manganese (Mn), titanium (Ti), tantalum (Ta), and aluminum (Al).

In one or more embodiments, the first major metal plug 176 of the first contact structure CT1 may include a metal inducing tensile strain in each of the first to third nanosheets N1, N2, and N3 of the nanosheet stack NSS corresponding to the first major metal plug 176, among the plurality of nanosheet stacks NSS arranged over the first fin-type active region F1. For example, the first major metal plug 176 of the first contact structure CT1 may include, but is not limited to, molybdenum (Mo).

In one or more embodiments, the second major metal plug 188 of the second contact structure CT2 may include a metal inducing compressive strain in each of the first to third nanosheets N1, N2, and N3 of the nanosheet stack NSS corresponding to the second major metal plug 188, among the plurality of nanosheet stacks NSS arranged over the second fin-type active region F2. For example, the second major metal plug 188 of the second contact structure CT2 may include, but is not limited to, tungsten (W), cobalt (Co), or a combination thereof.

In the first transistor TR1 constituting an NMOS transistor, because tensile strain is induced in each of the first to third nanosheets N1, N2, and N3 constituting the first transistor TR1 due to the first major metal plug 176 of the first contact structure CT1, effective mass may be increased in a channel region provided by the first to third nanosheets N1, N2, and N3, and thus, the mobility of holes in the channel region provided by the first to third nanosheets N1, N2, and N3 may be increased, thereby improving the performance of the first transistor TR1. In addition, in the second transistor TR2 constituting a PMOS transistor, because compressive strain is induced in each of the first to third nanosheets N1, N2, and N3 constituting the second transistor TR2 due to the second major metal plug 188 of the second contact structure CT2, effective mass may be reduced in a channel region provided by the first to third nanosheets N1, N2, and N3, and thus, the mobility of electrons in the channel region provided by the first to third nanosheets N1, N2, and N3 may be increased, thereby improving the performance of the second transistor TR2.

As shown in FIGS. 1 and 2, a cross-sectional shape of the first major metal plug 176 of the first contact structure CT1 may be different from a cross-sectional shape of the second major metal plug 188 of the second contact structure CT2. In one or more embodiments, as shown in FIGS. 1 and 2, when viewed in an X-Z plane, the first major metal plug 176 of the first contact structure CT1 may have a U-like cross-sectional shape defining an inner space thereof. In the second contact structure CT2, the second major metal plug 188 may have a pillar (i.e., unitary or solid) shape filled with a single metal in a horizontal direction (for example, the X direction in FIGS. 1 and 2) from the outer surface of the second major metal plug 188 to the inner center of the second major metal plug 188 without interruption.

In the first contact structure CT1, the first minor metal plug 178 may fill the inner space defined by the first major metal plug 176 and may be in contact with an inner surface of the first major metal plug 176. In the first contact structure CT1, the first minor metal plug 178 may include a metal that is different from a metal of the first major metal plug 176. For example, in the first contact structure CT1, the first major metal plug 176 may include molybdenum (Mo), and the first minor metal plug 178 may include tungsten (W), cobalt (Co), or a combination thereof.

In the first contact structure CT1, the first conductive barrier metal-containing film 174 may at least partially surround the first major metal plug 176 and the first minor metal plug 178. The first conductive barrier metal-containing film 174 may be in contact with outer surfaces of the first major metal plug 176, with the exception of the upper surface of the first major metal plug 176. In the first contact structure CT1, an outer surface of the first conductive barrier metal-containing film 174 may include a portion contacting the metal silicide film 172, a portion contacting the insulating spacer 118, and a portion contacting the capping insulating pattern 168. In one or more embodiments, the first conductive barrier metal-containing film 174 may include, but is not limited to, Ti, Ta, W, TiN, TaN, WN, WCN, TiSiN, TaSiN, WSiN, or a combination thereof. In the first contact structure CT1, the respective upper surfaces of the first conductive barrier metal-containing film 174, the first major metal plug 176, and the first minor metal plug 178 may form a flat coplanar surface.

In the second contact structure CT2, the second minor metal plug 186 may have a U-like cross-sectional shape at least partially surrounding the second major metal plug 188, when viewed in the X-Z plane. The second minor metal plug 186 may have an inner surface that defines an inner space accommodating the second major metal plug 188. The inner surface of the second minor metal plug 186 may be in contact with the outer surface of the second major metal plug 188. In the second contact structure CT2, the second minor metal plug 186 may include a metal that is different from a metal of the second major metal plug 188. For example, in the second contact structure CT2, the second minor metal plug 186 may include molybdenum (Mo), and the second major metal plug 188 may include tungsten (W), cobalt (Co), or a combination thereof.

In the second contact structure CT2, the second conductive barrier metal-containing film 184 may at least partially surround the second minor metal plug 186 and the second major metal plug 188. The second conductive barrier metal-containing film 184 may be in contact with outer surfaces of the second minor metal plug 186, with the exception of the upper surface of the second minor metal plug 186. In the second contact structure CT2, an outer surface of the second conductive barrier metal-containing film 184 may include a portion contacting the metal silicide film 172, a portion contacting the insulating spacer 118, and a portion contacting the capping insulating pattern 168. In one or more embodiments, the second conductive barrier metal-containing film 184 may include, but is not limited to, Ti, Ta, W, TiN, TaN, WN, WCN, TiSiN, TaSiN, WSiN, or a combination thereof. In one or more embodiments, the first conductive barrier metal-containing film 174 in the first device area I and the second conductive barrier metal-containing film 184 in the second device area II may include the same material, but the disclosure is not limited thereto. In the second contact structure CT2, the respective upper surfaces of the second conductive barrier metal-containing film 184, the second minor metal plug 186, and the second major metal plug 188 may form a flat coplanar surface.

In one or more embodiments, in the first device area I, the respective upper surfaces of the first conductive barrier metal-containing film 174, the first major metal plug 176, and the first minor metal plug 178 of the first contact structure CT1 and respective upper surfaces of a plurality of capping insulating patterns 168 in the first device area I may form a flat coplanar surface. In one or more embodiments, in the second device area II, the respective upper surfaces of the second conductive barrier metal-containing film 184, the second minor metal plug 186, and the second major metal plug 188 of the second contact structure CT2 and the respective upper surfaces of the plurality of capping insulating patterns 168 in the second device area II may form a flat coplanar surface.

In the integrated circuit device 100, a front-end-of-line (FEOL) structure may be arranged on the respective upper surfaces of the plurality of first contact structures CT1, the plurality of second contact structures CT2, and the plurality of capping insulating patterns 168. The FEOL structure may include wiring layers configured to be connected to the plurality of first contact structures CT1 and the plurality of second contact structures CT2.

The integrated circuit device 100 described with reference to FIGS. 1 and 2 includes the first contact structure CT1, which is connected to the first source/drain region 130A of the first transistor TR1 in the first device area I, and the second contact structure CT2, which is connected to the second source/drain region 130B of the second transistor TR2 in the second device area II. When the first transistor TR1 includes an NMOS transistor, the first major metal plug 176, which has the largest volume in the first contact structure CT1, may include a material that may induce tensile strain in each of the first to third nanosheets N1, N2, and N3 constituting the first transistor TR1. Therefore, effective mass may be increased in a channel region provided by the first to third nanosheets N1, N2, and N3 in the first transistor TR1, and thus, the mobility of holes in the channel region may be increased, thereby improving the performance of the first transistor TR1. When the second transistor TR2 includes a PMOS transistor, the second major metal plug 188, which has the largest volume in the second contact structure CT2, may include a material that may induce compressive strain in each of the first to third nanosheets N1, N2, and N3 constituting the second transistor TR2. Therefore, the mobility of electrons in the channel region provided by the first to third nanosheets N1, N2, and N3 in the second transistor TR2 may be increased, thereby improving the performance of the second transistor TR2.

As such, the integrated circuit device 100 according to one or more embodiments includes contact structures each having a structure capable of increasing carrier mobility and reducing contact resistance according to a channel type of a transistor, in each of transistors of different channel types, such as an NMOS transistor and a PMOS transistor.

Therefore, according to the integrated circuit device 100 according to one or more embodiments, the performance of each of the first and second transistors TR1 and TR2 may independently improve, and thus, the reliability of the integrated circuit device 100 may improve.

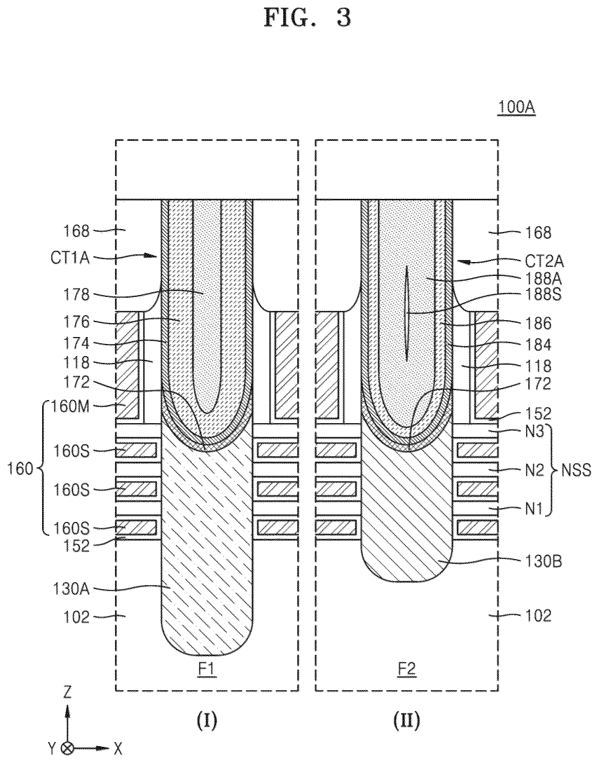

FIGS. 3 to 10 are cross-sectional views respectively illustrating integrated circuit devices 100A, 200, 200A, 300, 300A, 400, 400A, and 400B according to one or more embodiments. FIGS. 3 to 10 respectively illustrate enlarged cross-sectional configurations of regions, which correspond to the regions EX1 and EX2 in FIG. 1, of the integrated circuit devices 100A, 200, 200A, 300, 300A, 400, 400A, and 400B. In FIGS. 3 to 10, the same reference numerals as in FIGS. 1 and 2 respectively denote the same members, and here, repeated descriptions thereof are omitted.

Referring to FIG. 3, the integrated circuit device 100A has substantially the same configuration as the integrated circuit device 100 described with reference to FIGS. 1 and 2. However, the integrated circuit device 100A includes a first contact structure CT1A arranged in the first device area I and a second contact structure CT2A arranged in the second device area II.

The first contact structure CT1A and the second contact structure CT2A respectively have substantially the same configurations as those of the first contact structure CT1 and the second contact structure CT2 described with reference to FIGS. 1 and 2.

However, the second contact structure CT2A in the second device area II includes a second major metal plug 188A at least partially surrounded by the second minor metal plug 186. In the second contact structure CT2A, the second major metal plug 188A includes a seam 188S therein. The seam 188S may include an air gap region defined by the second major metal plug 188A. The air gap region constituting the seam 188S may include the atmosphere or include other gases that may be present during a fabrication process of the integrated circuit device 100A. The configuration of the second major metal plug 188A may be substantially the same as that of the second major metal plug 188 described with reference to FIGS. 1 and 2.

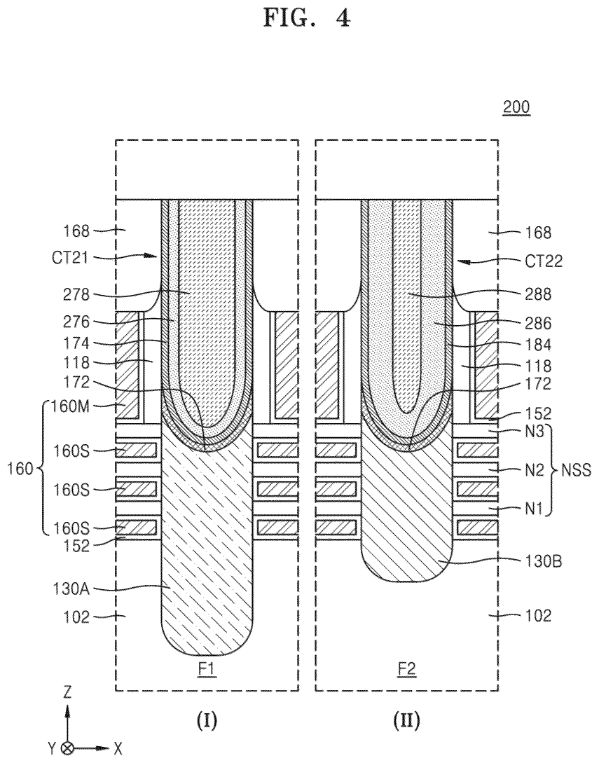

Referring to FIG. 4, the integrated circuit device 200 has substantially the same configuration as the integrated circuit device 100 described with reference to FIGS. 1 and 2. However, the integrated circuit device 200 includes a first contact structure CT21 arranged in the first device area I and a second contact structure CT22 arranged in the second device area II.

Each of the first contact structure CT21 and the second contact structure CT22 may include at least two metal-containing films. More specifically, in the first device area I, the first contact structure CT21 may include a first conductive barrier metal-containing film 174, a first minor metal plug 276, and a first major metal plug 278, which are sequentially stacked in the stated order on the metal silicide film 172. In the first contact structure CT21, at least two of the first conductive barrier metal-containing film 174, the first minor metal plug 276, and the first major metal plug 278 may respectively include different metals. In the second device area II, the second contact structure CT22 may include a second conductive barrier metal-containing film 184, a second major metal plug 286, and a second minor metal plug 288, which are sequentially stacked in the stated order on the metal silicide film 172. In the second contact structure CT22, at least two of the second conductive barrier metal-containing film 184, the second major metal plug 286, and the second minor metal plug 288 may respectively include different metals.

In the first contact structure CT21 in the first device area I, the first major metal plug 278 may have the largest volume, among metal-containing films of the first contact structure CT21. In one or more embodiments, in the first contact structure CT21, the volume of the first major metal plug 278 may be greater than the volume of the first minor metal plug 276, and the first minor metal plug 276 and the first major metal plug 278 may respectively include different metals.

In the second contact structure CT22 in the second device area II, the second major metal plug 286 may have the largest volume, among metal-containing films of the second contact structure CT22. In one or more embodiments, in the second contact structure CT22, the volume of the second major metal plug 286 may be greater than the volume of the second minor metal plug 288, and the second major metal plug 286 and the second minor metal plug 288 may respectively include different metals.

In one or more embodiments, each of the first contact structure CT21 and the second contact structure CT22 may include molybdenum (Mo), copper (Cu), tungsten (W), cobalt (Co), ruthenium (Ru), manganese (Mn), titanium (Ti), tantalum (Ta), aluminum (Al), titanium nitride (TiN), tantalum nitride (TaN), tungsten nitride (WN), tungsten carbonitride (WCN), titanium silicon nitride (TiSiN), tantalum silicon nitride (TaSiN), tungsten silicon nitride (WSiN), or a combination thereof.

In one or more embodiments, the first major metal plug 278 of the first contact structure CT21 and the second major metal plug 286 of the second contact structure CT22 may respectively include different metals selected from molybdenum (Mo), copper (Cu), tungsten (W), cobalt (Co), ruthenium (Ru), manganese (Mn), titanium (Ti), tantalum (Ta), and aluminum (Al).

In one or more embodiments, the first major metal plug 278 of the first contact structure CT21 may include a material inducing tensile strain in each of the first to third nanosheets N1, N2, and N3 in the nanosheet stack NSS corresponding to the first major metal plug 278, among the plurality of nanosheet stacks NSS arranged over the first fin-type active region F1. For example, the first major metal plug 278 of the first contact structure CT21 may include, but is not limited to, molybdenum (Mo).

In one or more embodiments, the second major metal plug 286 of the second contact structure CT22 may include a material inducing compressive strain in each of the first to third nanosheets N1, N2, and N3 in the nanosheet stack NSS corresponding to the second major metal plug 286, among the plurality of nanosheet stacks NSS arranged over the second fin-type active region F2. For example, the second major metal plug 286 of the second contact structure CT22 may include, but is not limited to, tungsten (W), cobalt (Co), or a combination thereof.

As shown in FIG. 4, a cross-sectional shape of the first major metal plug 278 of the first contact structure CT21 may be different from a cross-sectional shape of the second major metal plug 286 of the second contact structure CT22. In one or more embodiments, when viewed in the X-Z plane, the first major metal plug 278 of the first contact structure CT21 may have a pillar shape filled with a single, continuous, and solid metal in the horizontal direction (for example, the X direction in FIG. 3) from an outer surface of the first major metal plug 278 to an inner center of the first major metal plug 278 without interruption. In the second contact structure CT22, the second major metal plug 286 may have a U-like cross-sectional shape defining an inner space thereof.

In the first contact structure CT21, the first minor metal plug 276 may have a U-like cross-sectional shape to at least partially surround the first major metal plug 278, when viewed in the X-Z plane. The first minor metal plug 276 may have an inner surface that defines an inner space accommodating the first major metal plug 278. The inner surface of the first minor metal plug 276 may be in contact with the outer surface of the first major metal plug 278. In the first contact structure CT21, the first minor metal plug 276 may include a metal that is different from a metal of the first major metal plug 278. For example, in the first contact structure CT21, the first minor metal plug 276 may include tungsten (W), cobalt (Co), or a combination thereof, and the first major metal plug 278 may include molybdenum (Mo).

In the first contact structure CT21, the first conductive barrier metal-containing film 174 may at least partially surround the first minor metal plug 276 and the first major metal plug 278. The first conductive barrier metal-containing film 174 may be in contact with outer surfaces except for the upper surface from among outer surfaces of the first minor metal plug 276. In the first contact structure CT21, the respective upper surfaces of the first conductive barrier metal-containing film 174, the first minor metal plug 276, and the first major metal plug 278 may form a flat coplanar surface. In the first contact structure CT21, the configuration of the first conductive barrier metal-containing film 174 may be substantially the same as described with reference to FIGS. 1 and 2. Details of the constituent material of the first minor metal plug 276 of the first contact structure CT21 are substantially the same as those of the constituent material of the first minor metal plug 178 described with reference to FIGS. 1 and 2. Details of the constituent material of the first major metal plug 278 of the first contact structure CT21 are substantially the same as those of the constituent material of the first major metal plug 176 described with reference to FIGS. 1 and 2.

In one or more embodiments, in the first device area I of the integrated circuit device 200, the respective upper surfaces of the first conductive barrier metal-containing film 174, the first minor metal plug 276, and the first major metal plug 278 of the first contact structure CT21 and the respective upper surfaces of the plurality of capping insulating patterns 168 in the first device area I may form a flat coplanar surface.

In the second contact structure CT22 arranged in the second device area II of the integrated circuit device 200, the second major metal plug 286 may have a U-like cross-sectional shape defining an inner space thereof, and the second minor metal plug 288 may fill the inner space defined by the second major metal plug 286 and may be in contact with an inner surface of the second major metal plug 286. In the second contact structure CT22, the second minor metal plug 288 may include a metal that is different from a metal of the second major metal plug 286. For example, in the second contact structure CT22, the second major metal plug 286 may include tungsten (W), cobalt (Co), or a combination thereof, and the second minor metal plug 288 may include molybdenum (Mo).

In the second contact structure CT22, the second conductive barrier metal-containing film 184 may at least partially surround the second major metal plug 286 and the second minor metal plug 288. The second conductive barrier metal-containing film 184 may be in contact with outer surfaces except for the upper surface from among outer surfaces of the second major metal plug 286. In the second contact structure CT22, the outer surface of the second conductive barrier metal-containing film 184 may include a portion contacting the metal silicide film 172, a portion contacting the insulating spacer 118, and a portion contacting the capping insulating pattern 168. In the second contact structure CT22, the respective upper surfaces of the second conductive barrier metal-containing film 184, the second major metal plug 286, and the second minor metal plug 288 may form a flat coplanar surface. In the second contact structure CT22, the configuration of the second conductive barrier metal-containing film 184 may be substantially the same as described with reference to FIGS. 1 and 2. Details of the constituent material of the second major metal plug 286 of the second contact structure CT22 are substantially the same as those of the constituent material of the second major metal plug 188 described with reference to FIGS. 1 and 2.

Details of the constituent material of the second minor metal plug 288 of the second contact structure CT22 are substantially the same as those of the constituent material of the second minor metal plug 186 described with reference to FIGS. 1 and 2.

In one or more embodiments, in the second device area II of the integrated circuit device 200, the respective upper surfaces of the second conductive barrier metal-containing film 184, the second major metal plug 286, and the second minor metal plug 288 of the second contact structure CT22 and the respective upper surfaces of the plurality of capping insulating patterns 168 in the second device area II may form a flat coplanar surface.

In the integrated circuit device 200, an FEOL structure may be arranged on respective upper surfaces of a plurality of first contact structures CT21, a plurality of second contact structures CT22, and the plurality of capping insulating patterns 168. The FEOL structure may include wiring layers configured to be connected to the plurality of first contact structures CT21 and the plurality of second contact structures CT22.

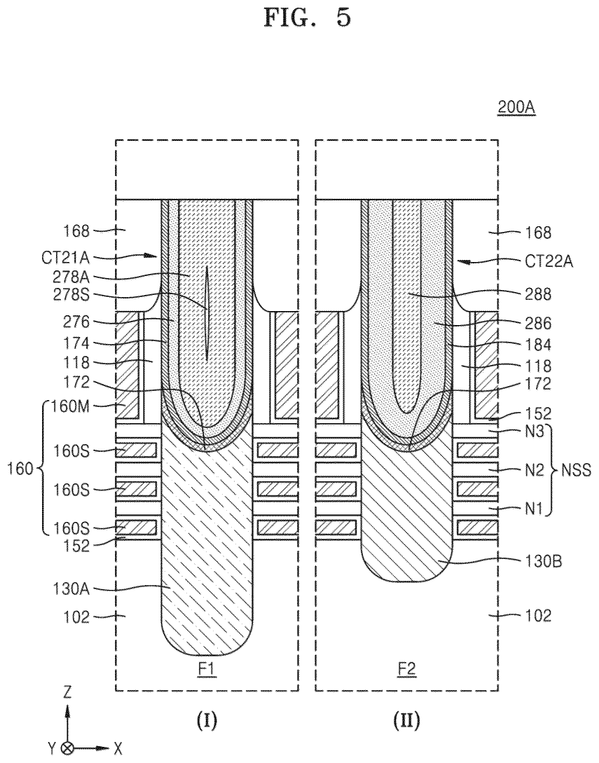

Referring to FIG. 5, the integrated circuit device 200A has substantially the same configuration as the integrated circuit device 200 described with reference to FIG. 4.

However, the integrated circuit device 200A includes a first contact structure CT21A arranged in the first device area I and a second contact structure CT22A arranged in the second device area II.

The first contact structure CT21A and the second contact structure CT22A respectively have substantially the same configurations as those of the first contact structure CT21 and the second contact structure CT22 described with reference to FIG. 4. However, the first contact structure CT21A in the first device area I includes a first major metal plug 278A at least partially surrounded by the first minor metal plug 276. In the first contact structure CT21A, the first major metal plug 278A includes a seam 278S therein. The seam 278S may include an air gap region defined by the first major metal plug 278A. The air gap region constituting the seam 278S may include the atmosphere or include other gases that may be present during a fabrication process of the integrated circuit device 200A. The configuration of the first major metal plug 278A may be substantially the same as that of the first major metal plug 278 described with reference to FIG. 4.

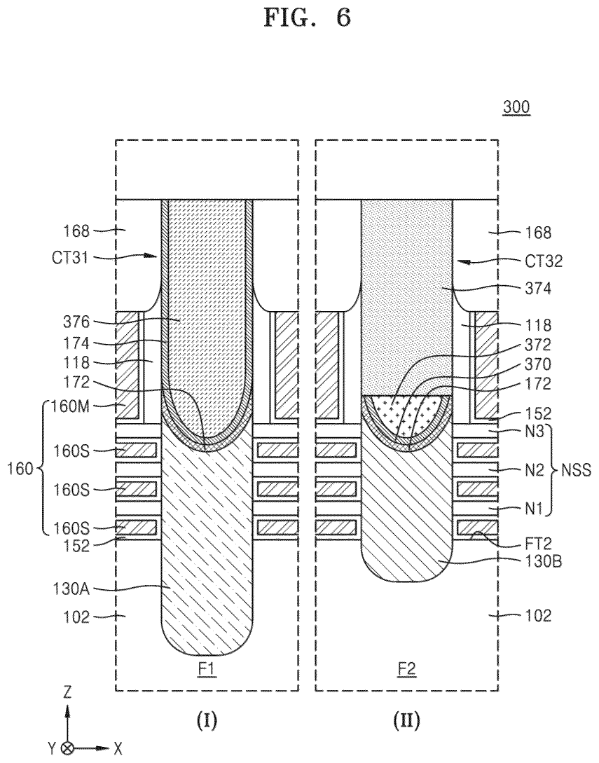

Referring to FIG. 6, the integrated circuit device 300 has substantially the same configuration as the integrated circuit device 100 described with reference to FIGS. 1 and 2. However, the integrated circuit device 300 includes a first contact structure CT31 arranged in the first device area I and a second contact structure CT32 arranged in the second device area II. Each of the first contact structure CT31 and the second contact structure CT32 may include at least two metal-containing films. More specifically, in the first device area I, the first contact structure CT31 may include a first conductive barrier metal-containing film 174 and a first major metal plug 376, which are sequentially stacked in the stated order on the metal silicide film 172. In the first contact structure CT31, the first conductive barrier metal-containing film 174 may at least partially surround the first major metal plug 376, and an inner surface of the first conductive barrier metal-containing film 174 may be in contact with an outer surface of the first major metal plug 376. In the first contact structure CT31, the first conductive barrier metal-containing film 174 and the first major metal plug 376 may respectively include different metals. The configuration of the first conductive barrier metal-containing film 174 of the first contact structure CT31 may be substantially the same as described with reference to FIGS. 1 and 2. The first major metal plug 376 of the first contact structure CT31 may fill an inner space defined by the first conductive barrier metal-containing film 174. The first major metal plug 376 may have a pillar shape filled with a single, continuous, and solid metal in the horizontal direction (for example, the X direction in FIG. 6) from the outer surface, which contacts the first conductive barrier metal-containing film 174, of the first major metal plug 376 to an inner center of the first major metal plug 376 without interruption. In one or more embodiments, the first major metal plug may be formed of a combination of one or more metals.

In the second device area II, the second contact structure CT32 may include a second conductive barrier metal-containing film 370, a lower metal plug 372, and a second major metal plug 374, which are sequentially stacked in the stated order on the metal silicide film 172. In the second contact structure CT32, at least two of the second conductive barrier metal-containing film 370, the lower metal plug 372, and the second major metal plug 374 may respectively include different metals. A constituent material of the second conductive barrier metal-containing film 370 of the second contact structure CT32 may be the same as that of the constituent material of the first conductive barrier metal-containing film 174 described with reference to FIGS. 1 and 2.

In the second device area II, the second major metal plug 374 of the second contact structure CT32 may have a pillar shape filled with a single, continuous, and solid metal in the horizontal direction from an outer surface thereof to an inner center thereof without interruption. In the second contact structure CT32, the second conductive barrier metal-containing film 370 may be arranged between the second source/drain region 130B and the second major metal plug 374 in the vertical direction (the Z direction) and may have an inner surface that is concave toward the second major metal plug 374. The lower metal plug 372 may be arranged between the second conductive barrier metal-containing film 370 and the second major metal plug 374 in the vertical direction (the Z direction). The lower metal plug 372 may have a convex surface contacting the concave inner surface of the second conductive barrier metal-containing film 370. In the second contact structure CT32, all portions of each of the second conductive barrier metal-containing film 370 and the lower metal plug 372 may be arranged between the second source/drain region 130B and the second major metal plug 374. All portions of each of the second conductive barrier metal-containing film 370 and the lower metal plug 372 may overlap the second major metal plug 374 in the vertical direction (the Z direction). The uppermost surface of each of the second conductive barrier metal-containing film 370 and the lower metal plug 372 may be in contact with a lower surface of the second major metal plug 374. The lower surface of the second major metal plug 374 may be a surface facing the second source/drain region 130B corresponding thereto.

In the vertical direction (the Z direction), a first length of the first major metal plug 376 of the first contact structure CT31 may be greater than a second length of the second major metal plug 374 of the second contact structure CT32.

In the first contact structure CT31 arranged in the first device area I, the first major metal plug 376 may have the largest volume, among metal-containing films of the first contact structure CT31. That is, the volume of the first major metal plug 376 may be greater than the volume of the first conductive barrier metal-containing film 174, and the first major metal plug 376 and the first conductive barrier metal-containing film 174 may respectively include different metals.

The lower metal plug 372 of the second contact structure CT32 may include molybdenum (Mo), copper (Cu), tungsten (W), cobalt (Co), ruthenium (Ru), manganese (Mn), titanium (Ti), tantalum (Ta), aluminum (Al), titanium (Ti), or a combination thereof. In one or more embodiments, at least two of the second conductive barrier metal-containing film 370, the lower metal plug 372, and the second major metal plug 374 may respectively include different metals. For example, the lower metal plug 372 and the second major metal plug 374 of the second contact structure CT32 may include the same material selected from tungsten (W) and cobalt (Co) or may respectively include different materials selected from tungsten (W) and cobalt (Co). The second conductive barrier metal-containing film 370 may include Ti, Ta, W, TiN, TaN, WN, WCN, TiSiN, TaSiN, WSiN, or a combination thereof.

In the second contact structure CT32 arranged in the second device area II, the second major metal plug 374 may have the largest volume, among metal-containing films of the second contact structure CT32. In one or more embodiments, in the second contact structure CT32, the volume of the second major metal plug 374 may be greater than the volume of each of the second conductive barrier metal-containing film 370 and the lower metal plug 372.

In one or more embodiments, the first major metal plug 376 of the first contact structure CT31 and the second major metal plug 374 of the second contact structure CT32 may respectively include different metals selected from molybdenum (Mo), copper (Cu), tungsten (W), cobalt (Co), ruthenium (Ru), manganese (Mn), titanium (Ti), tantalum (Ta), and aluminum (Al).

In one or more embodiments, the first major metal plug 376 of the first contact structure CT31 may include a metal inducing tensile strain in each of the first to third nanosheets N1, N2, and N3 of the nanosheet stack NSS corresponding to the first major metal plug 376, among the plurality of nanosheet stacks NSS arranged over the first fin-type active region F1. For example, the first major metal plug 376 of the first contact structure CT31 may include molybdenum (Mo).

In one or more embodiments, at least the second major metal plug 374 out of the lower metal plug 372 and the second major metal plug 374, which are included in the second contact structure CT32, may include a metal inducing compressive strain in each of the first to third nanosheets N1, N2, and N3 of the nanosheet stack NSS corresponding to the second major metal plug 374, among the plurality of nanosheet stacks NSS arranged over the second fin-type active region F2. For example, at least the second major metal plug 374 out of the lower metal plug 372 and the second major metal plug 374, which are included in the second contact structure CT32, may include tungsten (W), cobalt (Co), or a combination thereof.

As shown in FIG. 6, a cross-sectional shape of the first major metal plug 376 of the first contact structure CT31 may be different from a cross-sectional shape of the second major metal plug 374 of the second contact structure CT32. That is, although each of the first major metal plug 376 and the second major metal plug 374 has a pillar shape filled with a single, continuous, and solid metal in the horizontal direction from the outer surface thereof to the inner center thereof without interruption when viewed in the X-Z plane, the first major metal plug 376 and the second major metal plug 374 may respectively have different sizes in the vertical direction (the Z direction).

In one or more embodiments, in the first device area I of the integrated circuit device 300, the respective upper surfaces of the first conductive barrier metal-containing film 174 and the first major metal plug 376 of the first contact structure CT31 and the respective upper surfaces of the plurality of capping insulating patterns 168 in the first device area I may form a flat coplanar surface.

In one or more embodiments, in the second device area II of the integrated circuit device 300, the upper surface of the second major metal plug 374 of the second contact structure CT32 and the respective upper surfaces of the plurality of capping insulating patterns 168 in the second device area II may form a flat coplanar surface. A vertical level of each of the second conductive barrier metal-containing film 370 and the lower metal plug 372 of the second contact structure CT32 may be closer to the second fin top surface FT2 of the second fin-type active region F2 than a vertical level of the upper surface of the gate line 160 adjacent to the second contact structure CT32.

In the second contact structure CT32 arranged in the second device area II of the integrated circuit device 300, the second major metal plug 374 may fill a space defined by a first outer sidewall of each of a pair of insulating spacers 118 and a second outer sidewall of each of a pair of the capping insulating patterns 168 on the pair of insulating spacers 118 and may be in contact with the first and second outer sidewalls, the pair of insulating spacers 118 respectively covering sidewalls of a pair of gate lines 160 that are adjacent to the second contact structure CT32 when viewed in a cross-section in the first horizontal direction (the X direction). In the second contact structure CT32 arranged in the second device area II, another film including a nitride, for example, a conductive barrier film including a metal nitride such as TiN, TaN, or WN, may not be arranged between the second major metal plug 374 and the insulating spacer 118 and between the second major metal plug 374 and the capping insulating pattern 168. Accordingly, in the second contact structure CT32 arranged in the second device area II, the volume occupied by a conductive barrier film including a metal nitride may be minimized. Therefore, due to the second contact structure CT32, compressive strain may be more effectively induced in each of the first to third nanosheets N1, N2, and N3 of the nanosheet stack NSS corresponding to the second contact structure CT32, among the plurality of nanosheet stacks NSS arranged over the second fin-type active region F2, and contact resistance in the second contact structure CT32 may be reduced.

In the integrated circuit device 300, an FEOL structure may be arranged on the respective upper surfaces of a plurality of first contact structures CT31, a plurality of second contact structures CT32, and the plurality of capping insulating patterns 168. The FEOL structure may include wiring layers configured to be connected to the plurality of first contact structures CT31 and the plurality of second contact structures CT32.

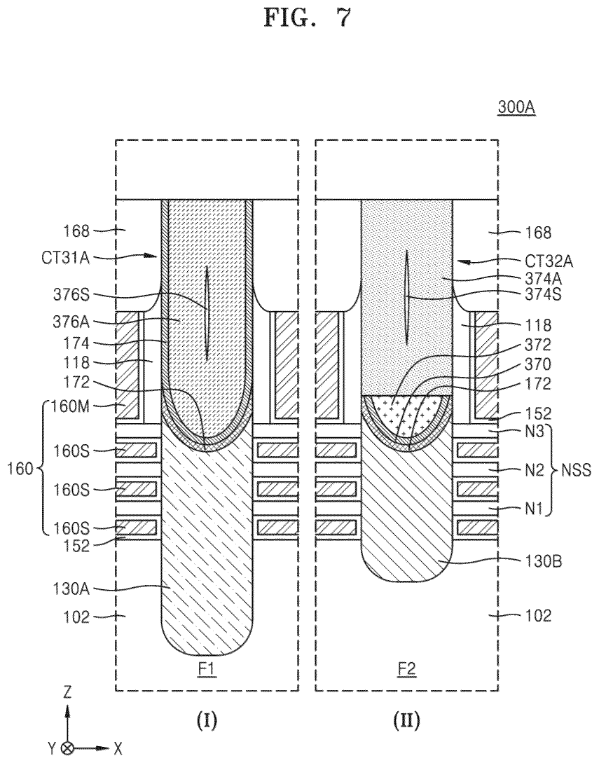

Referring to FIG. 7, the integrated circuit device 300A has substantially the same configuration as the integrated circuit device 300 described with reference to FIG. 6.

However, the integrated circuit device 300A includes a first contact structure CT31A arranged in the first device area I and a second contact structure CT32A arranged in the second device area II.

The first contact structure CT31A and the second contact structure CT32A respectively have substantially the same configurations as the first contact structure CT31 and the second contact structure CT32 described with reference to FIG. 6. However, the first contact structure CT31A arranged in the first device area I includes a first major metal plug 376A at least partially surrounded by the first conductive barrier metal-containing film 174. In the first contact structure CT31A, the first major metal plug 376A includes a seam 376S therein. In addition, the second contact structure CT32A arranged in the second device area II includes a second major metal plug 374A arranged to overlap each of the second conductive barrier metal-containing film 370 and the lower metal plug 372 in the vertical direction (the Z direction). In the second contact structure CT32A, the second major metal plug 374A includes a seam 374S therein.

The seam 376S in the first major metal plug 376A may include a first air gap region defined by the first major metal plug 376A, and the seam 374S in the second major metal plug 374A may include a second air gap region defined by the second major metal plug 374A. Each of the first and second air gap regions may include the atmosphere or include other gases that may be present during a fabrication process of the integrated circuit device 300A. In one or more embodiments, one of the seam 376S in the first major metal plug 376A and the seam 374S in the second major metal plug 374A may be omitted.

The configuration of the first major metal plug 376A may be substantially the same as that of the first major metal plug 376 described with reference to FIG. 6. The configuration of the second major metal plug 374A may be substantially the same as that of the second major metal plug 374 described with reference to FIG. 6.

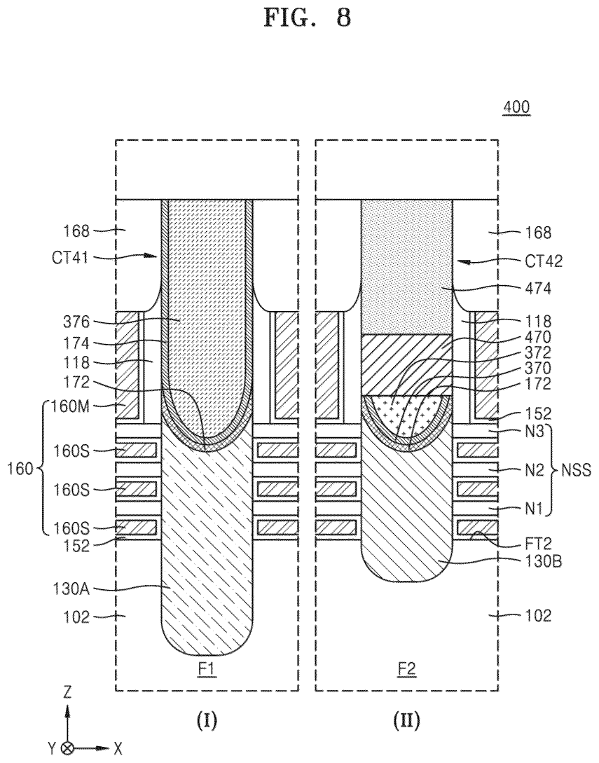

Referring to FIG. 8, the integrated circuit device 400 has substantially the same configuration as the integrated circuit device 300 described with reference to FIG. 6.

However, the integrated circuit device 400 includes a first contact structure CT41 arranged in the first device area I and a second contact structure CT42 arranged in the second device area II.

The first contact structure CT41 of the integrated circuit device 400 has the same structure as that of the first contact structure CT31 of the integrated circuit device 300 described with reference to FIG. 6. The second contact structure CT42 of the integrated circuit device 400 has substantially the same structure as that of the second contact structure CT32 of the integrated circuit device 300 described with reference to FIG. 6. However, the second contact structure CT42 of the integrated circuit device 400 includes an intermediate metal plug 470 and a second major metal plug 474, which are sequentially stacked in the stated order on the respective upper surfaces of the second conductive barrier metal-containing film 370 and the lower metal plug 372. Each of the intermediate metal plug 470 and the second major metal plug 474 may be arranged to overlap the second conductive barrier metal-containing film 370 and the lower metal plug 372 in the vertical direction (the Z direction).

In the second contact structure CT42 in the second device area II, the intermediate metal plug 470 may be arranged between the lower metal plug 372 and the second major metal plug 474 in the vertical direction (the Z direction). In the vertical direction (the Z direction), the height of the second major metal plug 474 may be greater than the height of the lower metal plug 372.

In the second contact structure CT42, at least two of the second conductive barrier metal-containing film 370, the lower metal plug 372, the intermediate metal plug 470, and the second major metal plug 474 may respectively include different metals. Detailed configurations of the second conductive barrier metal-containing film 370 and the lower metal plug 372 of the second contact structure CT42 are the same as described with reference to FIG. 6.

In the second device area II, each of the intermediate metal plug 470 and the second major metal plug 474 of the second contact structure CT42 may have a pillar shape filled with a single, continuous, and solid metal in the horizontal direction from an outer surface thereof to an inner center thereof without interruption. In the second contact structure CT42, the lower metal plug 372 may be arranged between the second conductive barrier metal-containing film 370 and the intermediate metal plug 470 in the vertical direction (the Z direction). Each of the second conductive barrier metal-containing film 370 and the lower metal plug 372 may be separated from the second major metal plug 474 in the vertical direction (the Z direction) with the intermediate metal plug 470 therebetween. A lower surface of the second major metal plug 474 may be in contact with an upper surface of the intermediate metal plug 470. The lower surface of the second major metal plug 474 may be a surface facing the second source/drain region 130B corresponding thereto.

In the vertical direction (the Z direction), a first length of the first major metal plug 376 of the first contact structure CT41 may be greater than a second length of the second major metal plug 474 of the second contact structure CT42.

Each of the lower metal plug 372 and the intermediate metal plug 470 of the second contact structure CT42 may include molybdenum (Mo), copper (Cu), tungsten (W), cobalt (Co), ruthenium (Ru), manganese (Mn), titanium (Ti), tantalum (Ta), aluminum (Al), titanium (Ti), or a combination thereof. In one or more embodiments, at least two of the second conductive barrier metal-containing film 370, the lower metal plug 372, the intermediate metal plug 470, and the second major metal plug 474 may respectively include different metals. For example, each of the lower metal plug 372, the intermediate metal plug 470, and the second major metal plug 474 of the second contact structure CT42 may include the same material selected from tungsten (W) and cobalt (Co). In one or more embodiments, two components adjacent to each other in the vertical direction (the Z direction) from among the lower metal plug 372, the intermediate metal plug 470, and the second major metal plug 474 may respectively include different materials selected from tungsten (W) and cobalt (Co). A constituent material of the second conductive barrier metal-containing film 370 may be the same as described with reference to FIG. 6.

In the second contact structure CT42 arranged in the second device area II, the second major metal plug 474 may have the largest volume, among metal-containing films of the second contact structure CT42. In one or more embodiments, in the second contact structure CT42, the volume of the second major metal plug 474 may be greater than the volume of each of the second conductive barrier metal-containing film 370, the lower metal plug 372, and the intermediate metal plug 470.

In one or more embodiments, each of the intermediate metal plug 470 and the second major metal plug 474 of the second contact structure CT42 may include a metal selected from molybdenum (Mo), copper (Cu), tungsten (W), cobalt (Co), ruthenium (Ru), manganese (Mn), titanium (Ti), tantalum (Ta), and aluminum (Al).

In one or more embodiments, at least the second major metal plug 474 from among the lower metal plug 372, the intermediate metal plug 470, and the second major metal plug 474 of the second contact structure CT42 may include a metal inducing compressive strain in each of the first to third nanosheets N1, N2, and N3 of the nanosheet stack NSS corresponding to the second major metal plug 474, among the plurality of nanosheet stacks NSS arranged over the second fin-type active region F2. For example, at least the second major metal plug 474 from among the lower metal plug 372, the intermediate metal plug 470, and the second major metal plug 474 of the second contact structure CT42 may include tungsten (W), cobalt (Co), or a combination thereof.

As shown in FIG. 8, a cross-sectional shape of the first major metal plug 376 of the first contact structure CT41 may be different from a cross-sectional shape of the second major metal plug 474 of the second contact structure CT42. That is, although each of the first major metal plug 376 and the second major metal plug 474 has a pillar shape filled with a single, continuous, and solid metal in the horizontal direction from the outer surface thereof to the inner center thereof without interruption when viewed in the X-Z plane, the first major metal plug 376 and the second major metal plug 474 may respectively have different sizes in the vertical direction (the Z direction). In the vertical direction (the Z direction), the size of the first major metal plug 376 of the first contact structure CT41 may be greater than the size of the second major metal plug 474 of the second contact structure CT42.

In one or more embodiments, in the second device area II of the integrated circuit device 400, the upper surface of the second major metal plug 474 of the second contact structure CT42 and the respective upper surfaces of the plurality of capping insulating patterns 168 in the second device area II may form a flat coplanar surface. A vertical level of the upper surface of the intermediate metal plug 470 of the second contact structure CT42 may be closer to the second fin top surface FT2 of the second fin-type active region F2 than a vertical level of the upper surface of the gate line 160 adjacent to the intermediate metal plug 470.

In the second contact structure CT42 arranged in the second device area II of the integrated circuit device 400, each of the intermediate metal plug 470 and the second major metal plug 474 may fill a space defined by a first outer sidewall of each of a pair of insulating spacers 118 and a second outer sidewall of each of a pair of the capping insulating patterns 168 on the pair of insulating spacers 118, the pair of insulating spacers 118 respectively covering sidewalls of a pair of gate lines 160 that are adjacent to each other when viewed in a cross-section in the first horizontal direction (the X direction). The second major metal plug 474 may be in contact with the first and second outer sidewalls, and the intermediate metal plug 470 may be in contact with the first outer sidewall. In the second contact structure CT42 arranged in the second device area II, another film including a nitride, for example, a conductive barrier film including a metal nitride such as TiN, TaN, or WN, may not be arranged between the second major metal plug 474 and the insulating spacer 118, between the second major metal plug 474 and the capping insulating pattern 168, and between the intermediate metal plug 470 and the insulating spacer 118. Accordingly, similar to the second contact structure CT32 described with reference to FIG. 6, in the second contact structure CT42 arranged in the second device area II, the volume occupied by a conductive barrier film including a metal nitride may be minimized. Therefore, due to the second contact structure CT42, compressive strain may be more effectively induced in each of the first to third nanosheets N1, N2, and N3 of the nanosheet stack NSS corresponding to the second contact structure CT42, among the plurality of nanosheet stacks NSS arranged over the second fin-type active region F2, and contact resistance in the second contact structure CT42 may be reduced.

In the integrated circuit device 400, an FEOL structure may be arranged on the respective upper surfaces of a plurality of first contact structures CT41, a plurality of second contact structures CT42, and the plurality of capping insulating patterns 168. The FEOL structure may include wiring layers configured to be connected to the plurality of first contact structures CT41 and the plurality of second contact structures CT42.

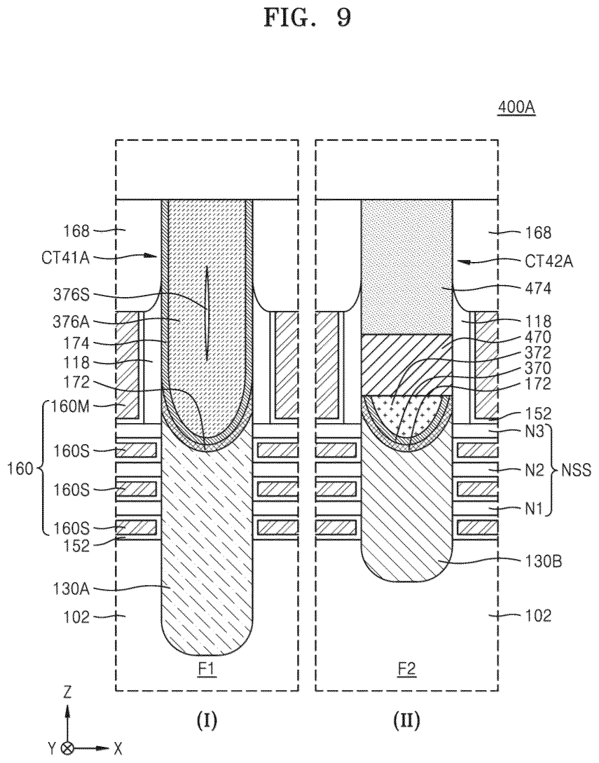

Referring to FIG. 9, the integrated circuit device 400A has substantially the same configuration as the integrated circuit device 400 described with reference to FIG. 8.

However, the integrated circuit device 400A includes a first contact structure CT41A arranged in the first device area I and a second contact structure CT42A arranged in the second device area II.

The first contact structure CT41A and the second contact structure CT42A respectively have substantially the same configurations as the first contact structure CT41 and the second contact structure CT42 described with reference to FIG. 8. However, the first contact structure CT41A arranged in the first device area I includes a first major metal plug 376A at least partially surrounded by the first conductive barrier metal-containing film 174. In the first contact structure CT41A, the first major metal plug 376A includes a seam 376S therein. The configuration of the first contact structure CT41A may be substantially the same as that of the first contact structure CT31A described with reference to FIG. 7. In the second contact structure CT42A arranged in the second device area II, each of the intermediate metal plug 470 and the second major metal plug 474 may not include a seam therein.

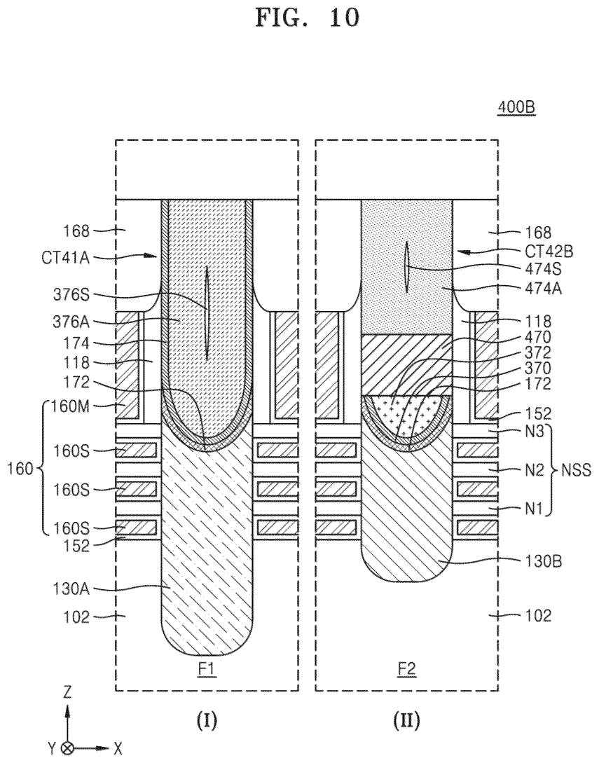

Referring to FIG. 10, the integrated circuit device 400B has substantially the same configuration as the integrated circuit device 400A described with reference to FIG. 9. However, the integrated circuit device 400B includes a first contact structure CT41A arranged in the first device area I and a second contact structure CT42B arranged in the second device area II.

The configuration of the first contact structure CT41A may be substantially the same as described with reference to FIG. 9. The second contact structure CT42B has substantially the same configuration as that of the second contact structure CT42 described with reference to FIG. 8. However, the second contact structure CT42B includes a second major metal plug 474A arranged to overlap each of the second conductive barrier metal-containing film 370, the lower metal plug 372, and the intermediate metal plug 470 in the vertical direction (the Z direction). In the second contact structure CT42B, the lower surface of the second major metal plug 474A may be in contact with the upper surface of the intermediate metal plug 470, and the second major metal plug 474A includes a seam 474S therein. The seam 474S in the second major metal plug 474A may include an air gap region defined by the second major metal plug 474A. The air gap region constituting the seam 278S may include the atmosphere or include other gases that may be present during a fabrication process of the integrated circuit device 400B. In the second contact structure CT42B, the intermediate metal plug 470 may not include a seam therein.

Similar to the integrated circuit device 100 described with reference to FIGS. 1 and 2, each of the integrated circuit devices 100A, 200, 200A, 300, 300A, 400, 400A, and 400B described with reference to FIGS. 3 to 10 includes contact structures that have structures capable of increasing carrier mobility and reducing contact resistance according to the channel type of a transistor in each of transistors of different channel types, such as an NMOS transistor and a PMOS transistor. Therefore, according to each of the integrated circuit devices 100A, 200, 200A, 300, 300A, 400, 400A, and 400B according to one or more embodiments, the performance of each of the first and second transistors TR1 and TR2 may independently improve, and thus, the reliability of each of the integrated circuit devices 100A, 200, 200A, 300, 300A, 400, 400A, and 400B may improve.

FIGS. 11A to 11H are cross-sectional views respectively illustrating a sequence of processes of a method of fabricating an integrated circuit device, according to one or more embodiments. An example of a method of fabricating the integrated circuit device 100 shown in FIGS. 1 and 2 is described with reference to FIGS. 11A to 11H. In FIGS. 11A to 11H, the same reference numerals as in FIGS. 1 and 2 respectively denote the same members, and here, repeated descriptions thereof are omitted.

Referring to FIG. 11A, in the first device area I and the second device area II, a plurality of sacrificial semiconductor layers 104 and a plurality of nanosheet semiconductor layers NS are alternately stacked one-by-one on the substrate 102. Each of the plurality of sacrificial semiconductor layers 104 and each of the plurality of nanosheet semiconductor layers NS may respectively include semiconductor materials having different etch selectivities. In one or more embodiments, each of the plurality of nanosheet semiconductor layers NS may include a Si layer and each of the plurality of sacrificial semiconductor layers 104 may include a SiGe layer. In one or more embodiments, the Ge content in the plurality of sacrificial semiconductor layers 104 may be constant. The SiGe layer constituting each of the plurality of sacrificial semiconductor layers 104 may have constant Ge content selected from a range of about 5 at % to about 60 at %, for example, about 10 at % to about 40 at %. The Ge content in the SiGe layer constituting each of the plurality of sacrificial semiconductor layers 104 may be variously selected, as needed.

In the first device area I and the second device area II, the plurality of nanosheet semiconductor layers NS, the plurality of sacrificial semiconductor layers 104, and the substrate 102 may be partially etched, thereby forming a plurality of first fin-type active regions F1, which extend lengthwise in the first horizontal direction (the X direction) in the first device area I, and a plurality of second fin-type active regions F2, which extend lengthwise in the first horizontal direction (the X direction) in the second device area II.

Although FIG. 11A illustrates one first fin-type active region F1 arranged in the first device area I and one second fin-type active region F2 arranged in the second device area II, the plurality of first fin-type active regions F1 may be arranged separate from each other in the second horizontal direction (the Y direction) on the substrate 102 in the first device area I, and the plurality of second fin-type active regions F2 may be arranged separate from each other in the second horizontal direction (the Y direction) on the substrate 102 in the second device area II.

Next, in the first device area I and the second device area II, a device isolation film may be formed to cover both sidewalls, in the second horizontal direction (the Y direction), of each of the plurality of first fin-type active regions F1 and the plurality of second fin-type active regions F2. A stack structure of the plurality of nanosheet semiconductor layers NS and the plurality of sacrificial semiconductor layers 104 may remain on the respective first and second fin top surfaces FT1 and FT2 of the plurality of first fin-type active regions F1 and the plurality of second fin-type active regions F2.

Referring to FIG. 11B, in the first device area I and the second device area II, a plurality of dummy gate structures DGS may be formed on the stack structure of the plurality of nanosheet semiconductor layers NS and the plurality of sacrificial semiconductor layers 104.

Each of the plurality of dummy gate structures DGS may extend lengthwise in the second horizontal direction (the Y direction). Each of the plurality of dummy gate structures DGS may have a structure in which an oxide film D122, a dummy gate layer D124, and a capping layer D126 are sequentially stacked in the stated order. In one or more embodiments, the dummy gate layer D124 may include polysilicon, and the capping layer D126 may include a silicon nitride film.

In the first device area I and the second device area II, a plurality of insulating spacers 118 may be formed to respectively cover both sidewalls of each of the plurality of dummy gate structures DGS, followed by etching a portion of each of the plurality of nanosheet semiconductor layers NS and the plurality of sacrificial semiconductor layers 104 and a portion of each of the first and second fin-type active regions F1 and F2 by using the plurality of dummy gate structures DGS and the plurality of insulating spacers 118 as an etch mask, thereby dividing the plurality of nanosheet semiconductor layers NS into a plurality of nanosheet stacks NSS and forming a plurality of first recesses R1 in the first fin-type active region F1 and a plurality of second recesses R2 in the second fin-type active region F2. Each of the plurality of nanosheet stacks NSS may include first to third nanosheets N1, N2, and N3. To form the plurality of first recesses R1 and the plurality of second recesses R2, the etching may be performed by dry etching, wet etching, or a combination thereof. A vertical level LV1 of the lowermost surface of each of the plurality of first recesses R1 and a vertical level LV2 of the lowermost surface of each of the plurality of second recesses R2 may be lower than vertical levels of the respective first and second fin top surfaces FT1 and FT2 of the first and second fin-type active regions F1 and F2, respectively. The vertical level LV1 of the lowermost surface of each of the plurality of first recesses R1 may be lower than the vertical level LV2 of the lowermost surface of each of the plurality of second recesses R2.

Referring to FIG. 11C, in the resulting product of FIG. 11B, a plurality of first source/drain regions 130A, which respectively fill the plurality of first recesses R1 in the first device area I, and a plurality of second source/drain regions 130B, which respectively fill the plurality of second recesses R2 in the second device area II, may be formed.

To form the plurality of first source/drain regions 130A, a semiconductor material may be epitaxially grown on the surface of each of the first fin-type active region F1 and the first to third nanosheets N1, N2, and N3, which are exposed in the plurality of first recesses R1 in the first device area I. In one or more embodiments, to form the plurality of first source/drain regions 130A, a low-pressure chemical vapor deposition (LPCVD) process, a selective epitaxial growth (SEG) process, or a cyclic deposition and etching (CDE) process may be performed. In one or more embodiments, the plurality of first source/drain regions 130A may each include a Si layer doped with an n-type dopant. To form the plurality of first source/drain regions 130A, silane (SiH₄), disilane (Si₂H₆), trisilane (Si₃H₈), dichlorosilane (SiH₂Cl₂), or the like may be used as a Si source. The n-type dopant may be selected from phosphorus (P), arsenic (As), and antimony (Sb).

To form the plurality of second source/drain regions 130B, a semiconductor material may be epitaxially grown on the surface of each of the second fin-type active region F2 and the first to third nanosheets N1, N2, and N3, which are exposed in the plurality of second recesses R2 in the second device area II. In one or more embodiments, to form the plurality of second source/drain regions 130B, an LPCVD process, an SEG process, or a CDE process may be performed by using source materials including an elemental semiconductor precursor. In one or more embodiments, the plurality of second source/drain regions 130B may each include a SiGe layer doped with a p-type dopant. To form the plurality of second source/drain regions 130B, a Si source and a Ge source may be used. Silane (SiH₄), disilane (Si₂H₆), trisilane (Si₃H₈), dichlorosilane (SiH₂Cl₂), or the like may be used as the Si source. Germane (GeH₄), digermane (Ge₂H₆), trigermane (Ge₃H₈), tetragermane (Ge₄H₁₀), dichlorogermane (Ge₂H₂Cl₂), or the like may be used as the Ge source. The p-type dopant may be selected from boron (B) and gallium (Ga).

A process of forming the plurality of first source/drain regions 130A and a process of forming the plurality of second source/drain regions 130B may be performed separately from each other. According to the need, the plurality of first source/drain regions 130A may be formed first, followed by forming the plurality of second source/drain regions 130B, or the plurality of second source/drain regions 130B may be formed first, followed by forming the plurality of first source/drain regions 130A.

Referring to FIG. 11D, in the first device area I and the second device area II, an insulating liner 142 may be formed to conformally cover the resulting product of FIG. 11C, followed by forming an inter-gate dielectric 144 on the insulating liner 142, and then, a portion of each of the insulating liner 142 and the inter-gate dielectric 144 may be etched, thereby exposing upper surfaces of a plurality of capping layers D126. Next, the dummy gate layer D124 may be exposed by removing the plurality of capping layers D126, and the insulating liner 142 and the inter-gate dielectric 144 may be partially removed such that the upper surface of the inter-gate dielectric 144 and the upper surface of the dummy gate layer D124 are at an approximately equal level.

Referring to FIG. 11E, a gate space GS may be prepared by removing the dummy gate layer D124 and the oxide film D122 thereunder in the first device area I and the second device area II from the resulting product of FIG. 11D, and the plurality of nanosheet stacks NSS may be exposed by the gate space GS. Next, the plurality of sacrificial semiconductor layers 104 remaining over the first and second fin-type active regions F1 and F2 in the first device area I and the second device area II may be removed through the gate space GS, thereby expanding the gate space GS to a space between each of the first to third nanosheets N1, N2, and N3 and to a space between the first nanosheet N1 and each of the first and second fin top surfaces FT1 and FT2. In one or more embodiments, to selectively remove the plurality of sacrificial semiconductor layers 104, a difference in etch selectivity between the first to third nanosheets N1, N2, and N3 and each of the plurality of sacrificial semiconductor layers 104 may be used.

To selectively remove the plurality of sacrificial semiconductor layers 104, a liquid-phase or gas-phase etchant may be used. In one or more embodiments, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but the disclosure is not limited thereto.

Referring to FIG. 11F, in the resulting product of FIG. 11E, a gate dielectric film 152 may be formed to cover respective exposed surfaces of the first to third nanosheets N1, N2, and N3 and the first and second fin-type active regions F1 and F2. To form the gate dielectric film 152, an atomic layer deposition (ALD) process may be used.

Referring to FIG. 11G, in the first device area I and the second device area II, a gate line 160 may be formed on the gate dielectric film 152 to fill the gate space GS (see FIG. 11E). Next, each of the gate line 160, the gate dielectric film 152, and the insulating spacer 118 may be partially removed from the upper surface thereof to reduce the height thereof, and a plurality of capping insulating patterns 168 may each be formed to cover the upper surface of each of the gate line 160, the gate dielectric film 152, and the insulating spacer 118.

In one or more embodiments, a plurality of gate lines 160 may each include a stack structure of a plurality of metal-containing films. Among the plurality of gate lines 160, the gate line 160 arranged in the first device area I and the gate line 160 arranged in the second device area II may respectively have different stack structures. For example, the gate line 160 in the first device area I and the gate line 160 in the second device area II may respectively have different stack structures selected from a stack structure of TiAlC/TiN/W, a stack structure of TiN/TaN/TiAlC/TiN/W, and a stack structure of TiN/TaN/TiN/TiAlC/TiN/W.

Referring to FIG. 11H, in the first device area I and the second device area II of the resulting product of FIG. 11G, a plurality of contact holes may be formed through an insulating structure including the insulating liner 142 and the inter-gate dielectric 144 to expose the plurality of first source/drain regions 130A and the plurality of second source/drain regions 130B. Next, processes may be performed to form a metal silicide film 172 and a first contact structure CT1, which are stacked in the stated order on the first source/drain region 130A in the first device area I, and a metal silicide film 172 and a second contact structure CT2, which are stacked in the stated order on the second source/drain region 130B in the second device area II.

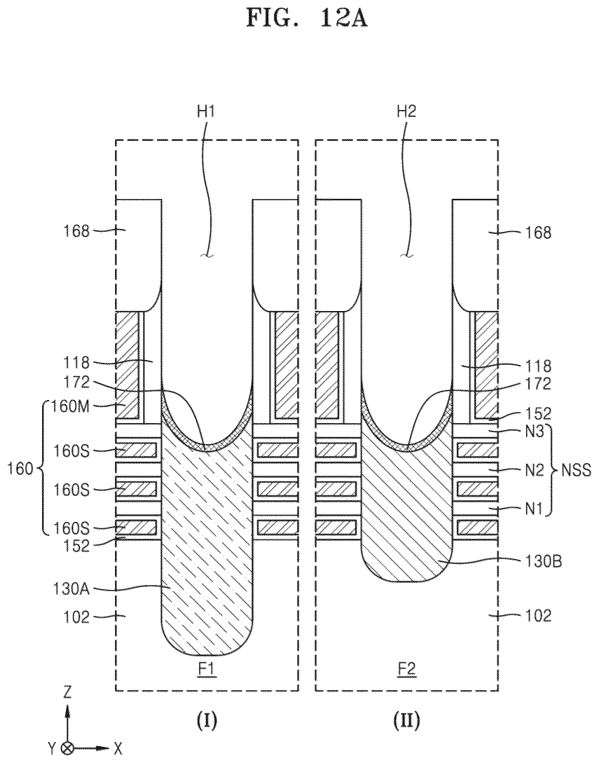

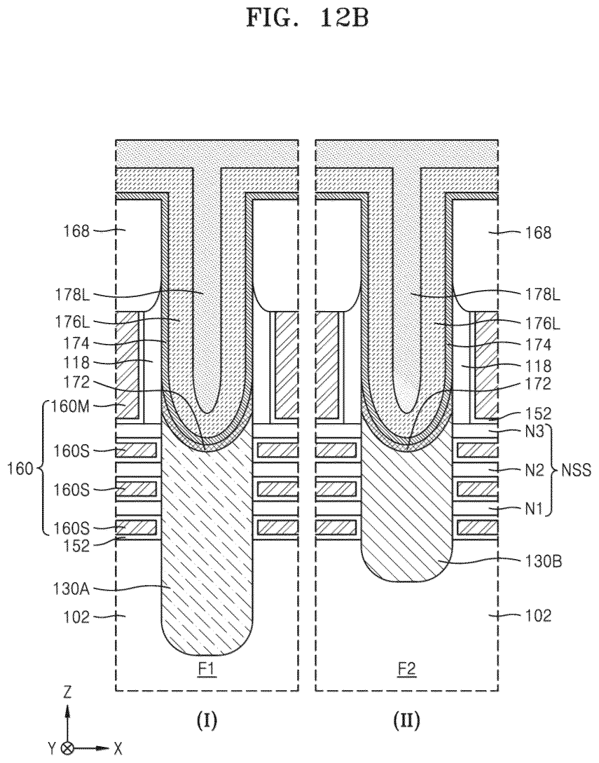

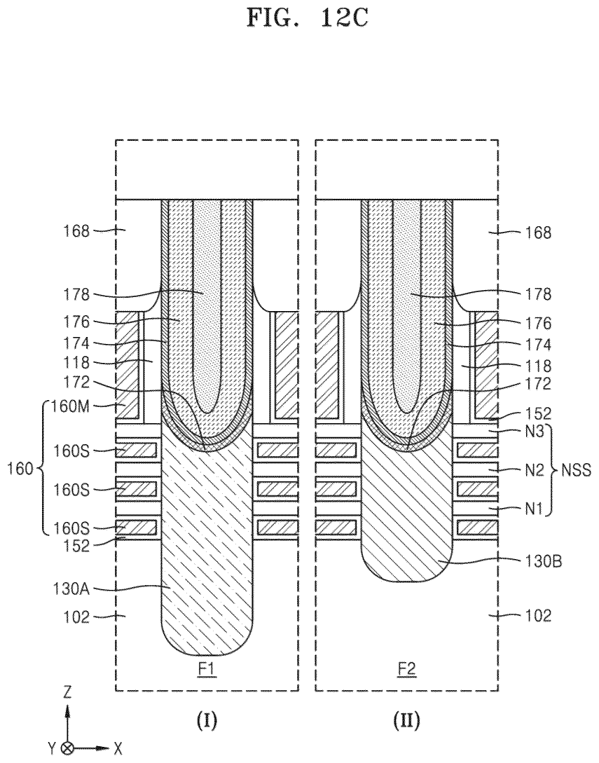

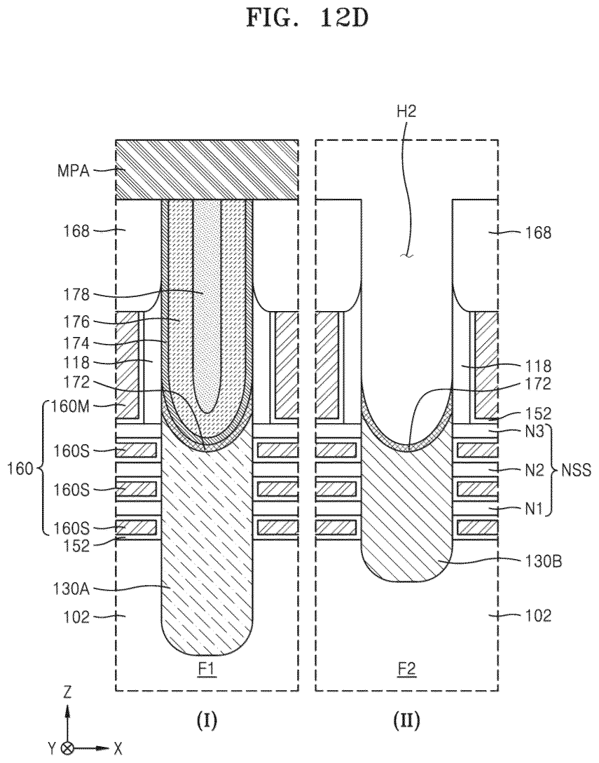

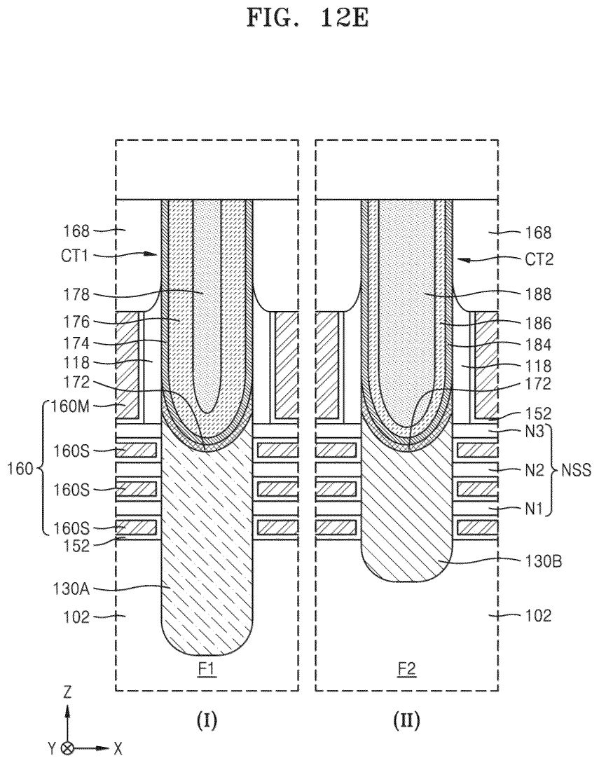

FIGS. 12A to 12E are enlarged cross-sectional views respectively illustrating, in more detail, a sequence of the processes described with reference to FIG. 11H. FIGS. 12A to 12E each illustrate components in regions respectively corresponding to the regions EX1 and EX2 of FIG. 11H according to the sequence of the processes. In FIGS. 12A to 12E, the same reference numerals as in FIGS. 1, 2, and 11A to 11H respectively denote the same members, and here, repeated descriptions thereof are omitted.

Referring to FIG. 12A, in the resulting product of FIG. 11G, the insulating structure including the insulating liner 142 and the inter-gate dielectric 144 may be etched, thereby forming a first contact hole H1, which exposes the first source/drain region 130A in the first device area I, and a second contact hole H2, which exposes the second source/drain region 130B in the second device area II. Next, a recess surface may be formed in the upper surface of each of the first and second source/drain regions 130A and 130B by etching a portion of each of the first and second source/drain regions 130A and 130B exposed by the first and second contact holes H1 and H2, and then, the metal silicide film 172 may be formed to cover the recess surface of each of the first and second source/drain regions 130A and 130B.

Referring to FIG. 12B, in the resulting product of FIG. 12A, a first conductive barrier metal-containing film 174, a first major metal film 176L, and a first minor metal film 178L may be formed in the stated order on the metal silicide film 172 to fill the first and second contact holes H1 and H2.

Each of the first conductive barrier metal-containing film 174, the first major metal film 176L, and the first minor metal film 178L may be formed by an ALD process or a CVD process. Constituent materials of the first major metal film 176L and the first minor metal film 178L are respectively the same as the constituent materials of the first major metal plug 176 and the first minor metal plug 178 described with reference to FIGS. 1 and 2.

In respective portions, which fill the first contact hole H1 in the first device area I, of the first conductive barrier metal-containing film 174, the first major metal film 176L, and the first minor metal film 178L, the volume of the first major metal film 176L may be greater than the volume of each of the first conductive barrier metal-containing film 174 and the first minor metal film 178L.

Referring to FIG. 12C, in the resulting product of FIG. 12B, respective portions, which are outside the first and second contact holes H1 and H2, of the first conductive barrier metal-containing film 174, the first major metal film 176L, and the first minor metal film 178L may be removed by an etch-back process and/or a chemical mechanical polishing (CMP) process, thereby exposing the respective upper surfaces of the plurality of capping insulating patterns 168. As a result, in the first device area I and the second device area II, the first major metal plug 176, which is a portion of the first major metal film 176L, and the first minor metal plug 178, which is a portion of the first minor metal film 178L, may remain on or over the first conductive barrier metal-containing film 174 in the first and second contact holes H1 and H2.

Referring to FIG. 12D, in the resulting product of FIG. 12C, a mask pattern MPA may be formed to cover the first device area I, followed by removing the first conductive barrier metal-containing film 174, the first major metal plug 176, and the first minor metal plug 178 from the second contact hole H2 in the second device area II by using the mask pattern MPA as an etch mask, thereby exposing the metal silicide film 172 in the second contact hole H2. In one or more embodiments, the mask pattern MPA may include at least one hardmask pattern or photoresist pattern or a combination thereof, the at least one hardmask pattern or photoresist patter including a material having etch selectivity with respect to the constituent material of each of the first conductive barrier metal-containing film 174, the first major metal plug 176, and the first minor metal plug 178.

Referring to FIG. 12E, a process of removing the mask pattern MPA, and a process of sequentially forming a second conductive barrier metal-containing film 184, a second minor metal plug 186, and a second major metal plug 188 in the stated order in the second contact hole H2 in the second device area II may be performed on the resulting product of FIG. 12D. To form the second conductive barrier metal-containing film 184, the second minor metal plug 186, and the second major metal plug 188, material films required to form these components may be formed by an ALD or CVD process, and then, portions of the material films, which are outside the second contact hole H2, may be removed by an etch-back process and/or a CMP process. In the process of forming the second conductive barrier metal-containing film 184, the second minor metal plug 186, and the second major metal plug 188 in the second contact hole H2, the volume of the second major metal plug 188 in the second contact hole H2 may be greater than the volume of each of the second conductive barrier metal-containing film 184 and the second minor metal plug 186 in the second contact hole H2.

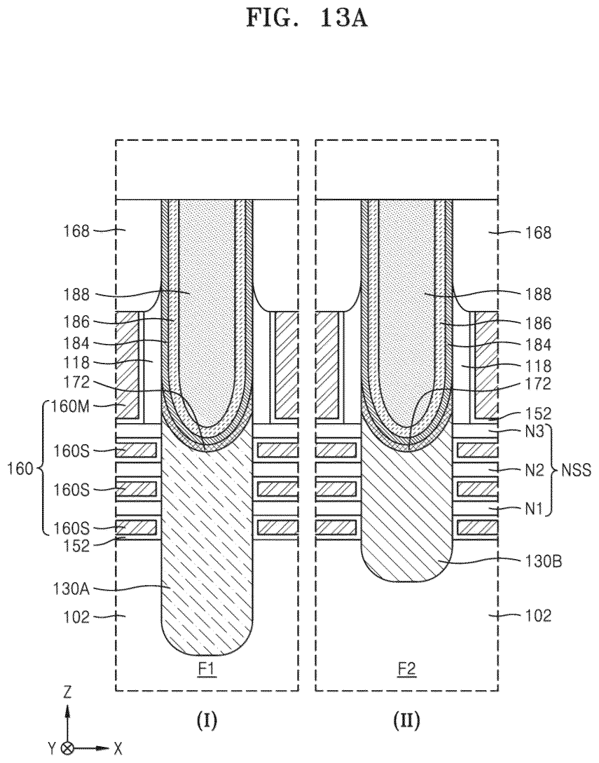

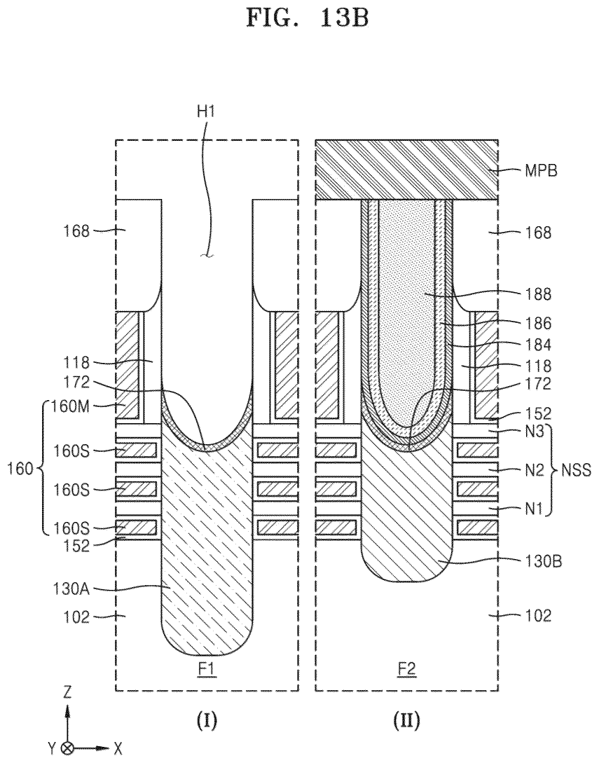

Although the processes of forming the first contact structure CT1 in the first device area I first and then forming the second contact structure CT2 in the second device area II are described above as an example with reference to FIGS. 12A to 12E, the disclosure is not limited thereto. For example, as described below with reference to FIGS. 13A and 13B, the second contact structure CT2 may be formed first in the second device area II, and then, the first contact structure CT1 may be formed in the first device area I.

FIGS. 13A and 13B are cross-sectional views respectively illustrating a sequence of processes of a method of fabricating an integrated circuit device, according to one or more embodiments. Another example of the method of fabricating the integrated circuit device 100 shown in FIGS. 1 and 2 is described with reference to FIGS. 13A and 13B. In FIGS. 13A and 13B, the same reference numerals as in FIGS. 1, 2, 11A to 11H, and 12A to 12E respectively denote the same members, and here, repeated descriptions thereof are omitted.

Referring to FIG. 13A, the processes described with reference to FIGS. 11A to 11G and 12A may be performed, and then, a process of sequentially forming the second conductive barrier metal-containing film 184, the second minor metal plug 186, and the second major metal plug 188 on the metal silicide film 172 to fill the first and second contact holes H1 and H2 may be performed on the resulting product of FIG. 12A. Here, in the second contact hole H2, the volume of the second major metal plug 188 may be greater than the volume of each of the second conductive barrier metal-containing film 184 and the second minor metal plug 186.

Referring to FIG. 13B, in the resulting product of FIG. 13A, a mask pattern MPB may be formed to cover the second device area II, followed by removing the second conductive barrier metal-containing film 184, the second minor metal plug 186, and the second major metal plug 188 from the first contact hole H1 in the first device area I by using the mask pattern MPB as an etch mask, thereby exposing the metal silicide film 172 in the first contact hole H1. In one or more embodiments, the mask pattern MPB may include at least one hardmask pattern or photoresist pattern or a combination thereof, the at least one hardmask pattern or photoresist patter including a material having etch selectivity with respect to the constituent material of each of the second conductive barrier metal-containing film 184, the second minor metal plug 186, and the second major metal plug 188.

Next, a process of removing the mask pattern MPB, and a process of forming the first contact structure CT1 shown in FIGS. 1 and 2 by forming the first conductive barrier metal-containing film 174, the first major metal plug 176, and the first minor metal plug 178 in the first contact hole H1 in the first device area I may be performed on the resulting product of FIG. 12D.

To fabricate the integrated circuit device 100A shown in FIG. 3, the processes described with reference to FIGS. 11A to 11G may be performed, and then, similar processes to the processes described with reference to FIGS. 12A to 12E or to the processes described with reference to FIGS. 13A and 13B may be performed. However, in the process described with reference to FIG. 12E or the process described with reference to FIG. 13A, a second major metal plug 188A, instead of the second major metal plug 188, may be formed in the second contact hole H2 in the second device area II. While an ALD or CVD process is being performed to form the second major metal plug 188A, a seam 188S may be formed in the second major metal plug 188A to extend lengthwise in the vertical direction (the Z direction).

To fabricate the integrated circuit device 200 shown in FIG. 4, the processes described with reference to FIGS. 11A to 11G may be performed, and then, similar processes to the processes described with reference to FIGS. 12A to 12E or to the processes described with reference to FIGS. 13A and 13B may be performed. However, a first contact structure CT21 including a first conductive barrier metal-containing film 174, a first minor metal plug 276, and a first major metal plug 278, which are sequentially stacked in the stated order on the metal silicide film 172, may be formed in the first device area I, and a second contact structure CT22 including a second conductive barrier metal-containing film 184, a second major metal plug 286, and a second minor metal plug 288, which are sequentially stacked in the stated order on the metal silicide film 172, may be formed in the second device area II.

To fabricate the integrated circuit device 200A shown in FIG. 5, the processes described with reference to FIGS. 11A to 11G may be performed, followed by performing similar processes to the processes described with reference to FIGS. 12A to 12E or to the processes described with reference to FIGS. 13A and 13B, thereby forming a structure as in the fabrication process of the integrated circuit device 200 shown in FIG. 4. However, a first major metal plug 278A, instead of the first major metal plug 278, may be formed in the first contact hole H1 in the first device area I. While an ALD or CVD process is being performed to form the first major metal plug 278A, a seam 278S may be formed in the first major metal plug 278A to extend lengthwise in the vertical direction (the Z direction).

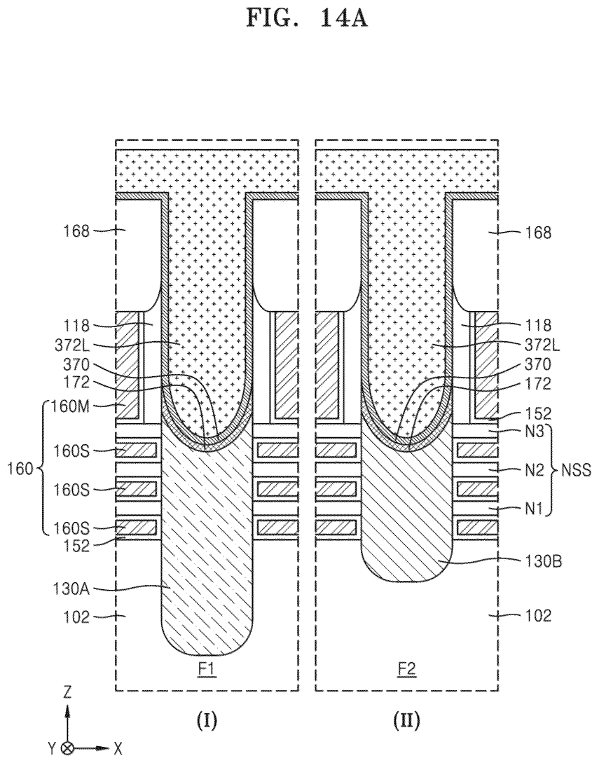

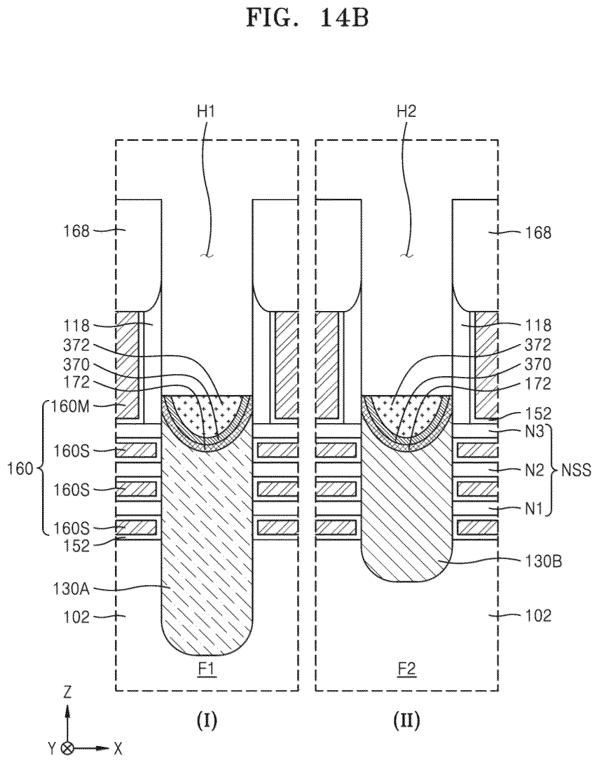

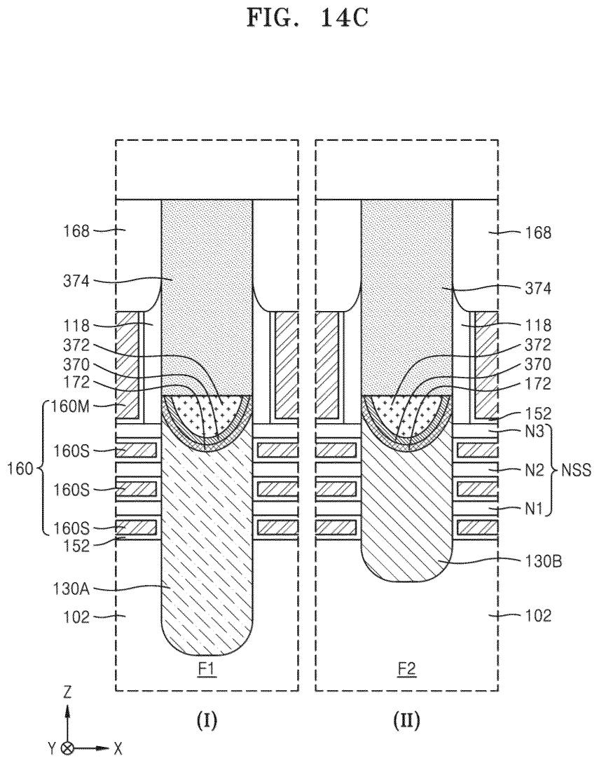

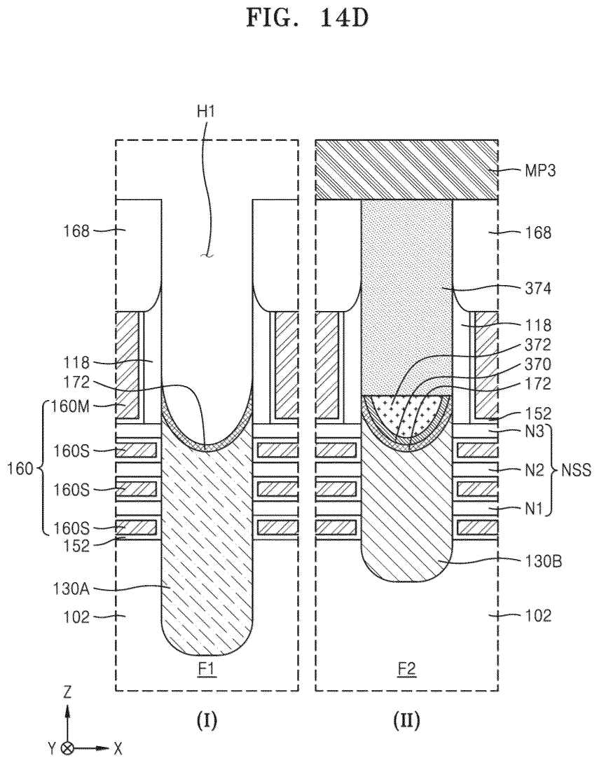

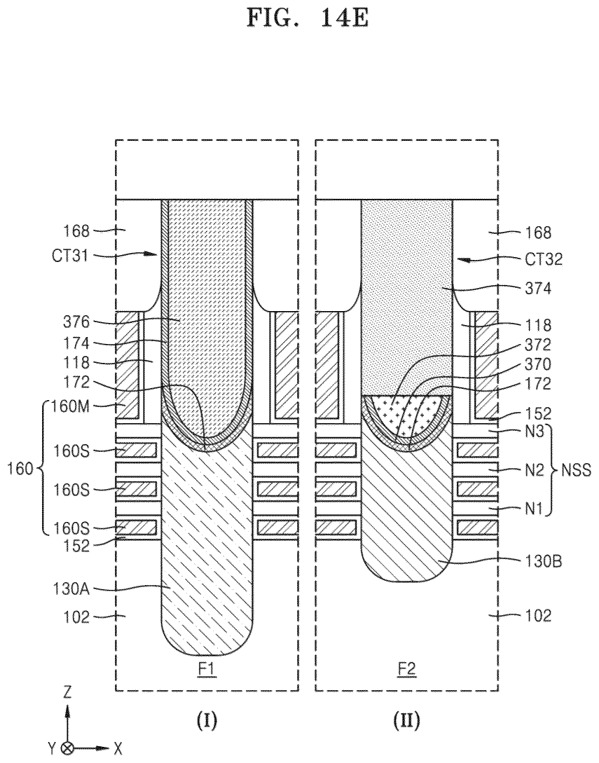

FIGS. 14A to 14E are cross-sectional views respectively illustrating a sequence of processes of a method of fabricating an integrated circuit device, according to one or more embodiments. FIGS. 14A to 14E each illustrate components in regions respectively corresponding to the regions EX1 and EX2 of FIG. 11H according to the sequence of processes. An example of a method of fabricating the integrated circuit device 300 shown in FIG. 6 is described with reference to FIGS. 14A to 14E. In FIGS. 14A to 14E, the same reference numerals as in FIGS. 1 to 5 and 11A to 11H respectively denote the same members, and here, repeated descriptions thereof are omitted.

Referring to FIG. 14A, the processes described with reference to FIGS. 11A to 11G and 12A may be performed, and then, a process of sequentially forming a second conductive barrier metal-containing film 370 and a lower metal film 372L in the stated order on the metal silicide film 172 to fill the first and second contact holes H1 and H2 may be performed on the resulting product of FIG. 12A.

Referring to FIG. 14B, in the resulting product of FIG. 14A, a portion of each of the second conductive barrier metal-containing film 370 and the lower metal film 372L may be removed by an etch-back process, thereby emptying a portion of each of the first and second contact holes H1 and H2 again. As a result, in each of the first and second contact holes H1 and H2, a portion of the second conductive barrier metal-containing film 370, and the lower metal plug 372 that is a portion of the lower metal film 372L may remain on or over the metal silicide film 172.

Referring to FIG. 14C, in the resulting product of FIG. 14B, a second major metal plug 374 may be formed to fill the remaining space of each of the first and second contact holes H1 and H2. In one or more embodiments, to form the second major metal plug 374, an ALD or CVD process may be used. In one or more embodiments, in the first device area I and the second device area II, the second major metal plug 374 may be formed to contact the insulating spacer 118 and the capping insulating pattern 168.

Referring to FIG. 14D, in the resulting product of FIG. 14C, a mask pattern MP3 may be formed to cover the second device area II, followed by removing the second major metal plug 374, the lower metal plug 372, and the second conductive barrier metal-containing film 370 from the first contact hole H1 in the first device area I by using the mask pattern MP3 as an etch mask, thereby exposing the metal silicide film 172 in the first contact hole H1.

Referring to FIG. 14E, a process of removing the mask pattern MP3, and a process of forming a first conductive barrier metal-containing film 174 and a first major metal plug 376 in the first contact hole H1 in the first device area I may be performed on the resulting product of FIG. 14D. Each of the first conductive barrier metal-containing film 174 and the first major metal plug 376 may be formed by an ALD or CVD process.

To fabricate the integrated circuit device 300A shown in FIG. 7, similar processes to those described with reference to FIGS. 14A to 14E may be performed. However, in the process described with reference to FIG. 14C, a second major metal plug 374A, instead of the second major metal plug 374, may be formed in the second contact hole H2 in the second device area II. While an ALD or CVD process is being performed to form the second major metal plug 374A, a seam 374S may be formed in the second major metal plug 374A to extend lengthwise in the vertical direction (the Z direction). In addition, in the process described with reference to FIG. 14E, a first major metal plug 376A, instead of the first major metal plug 376, may be formed in the first contact hole H1 in the first device area I. While an ALD or CVD process is being performed to form the first major metal plug 376A, a seam 376S may be formed in the first major metal plug 376A to extend lengthwise in the vertical direction (the Z direction).

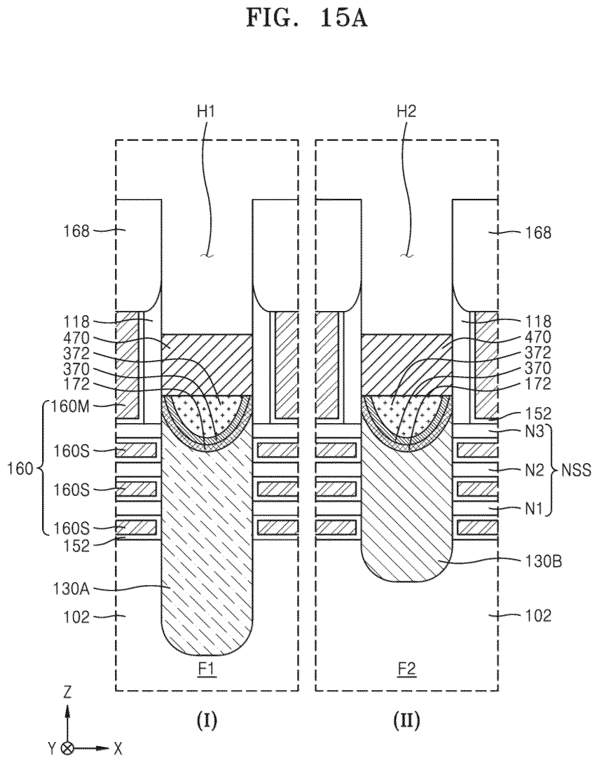

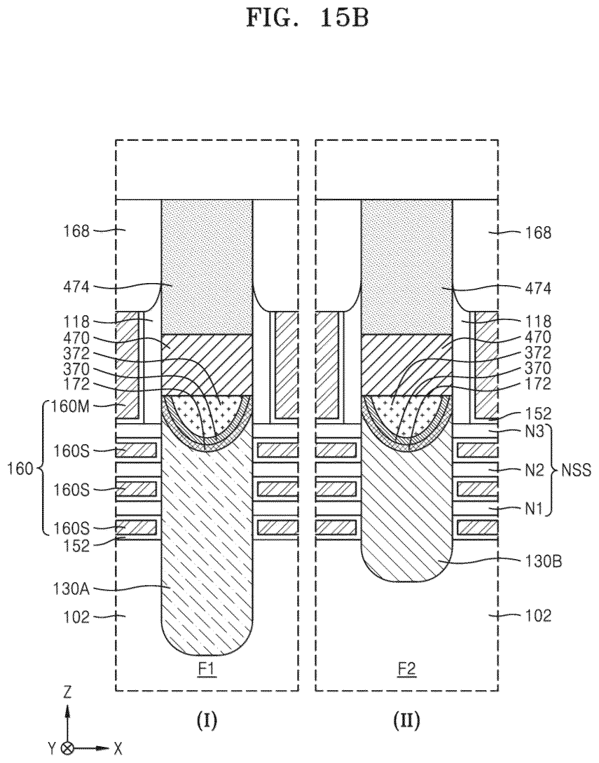

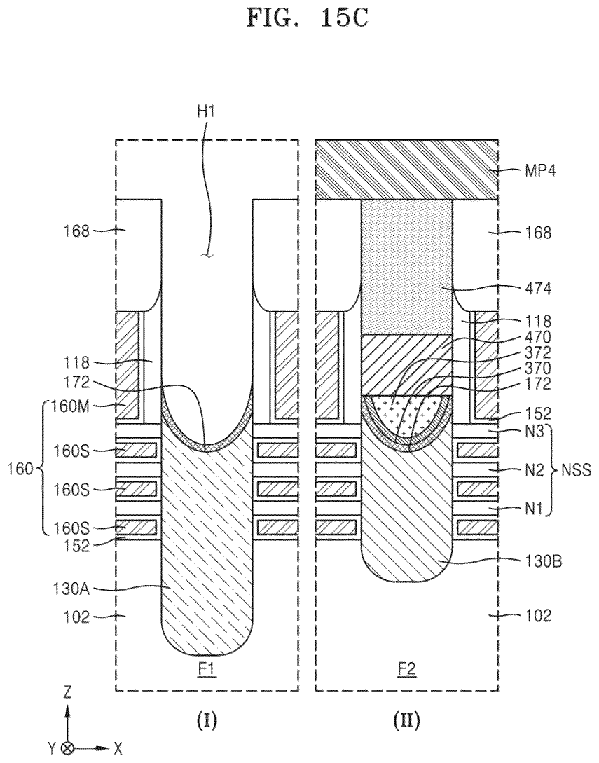

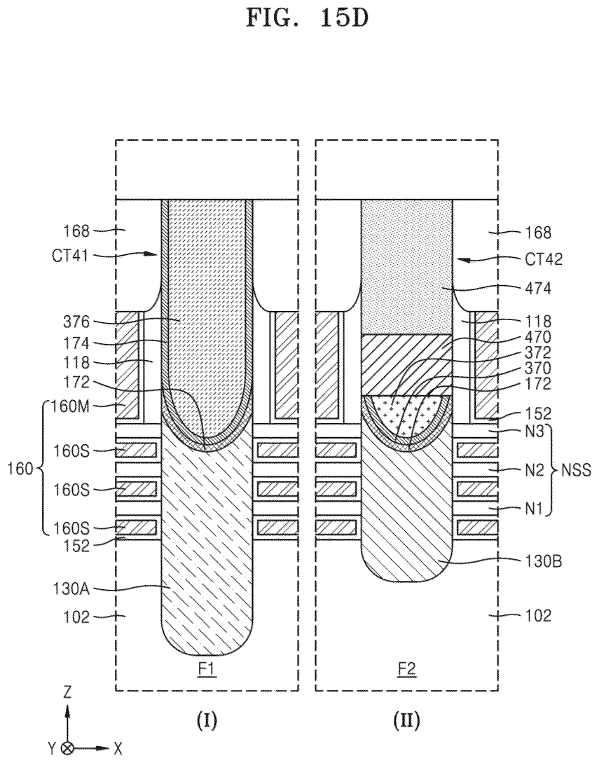

FIGS. 15A to 15D are cross-sectional views respectively illustrating a sequence of processes of a method of fabricating an integrated circuit device, according to one or more embodiments. FIGS. 15A to 15D each illustrate components in regions respectively corresponding to the regions EX1 and EX2 of FIG. 11H according to the sequence of processes. An example of a method of fabricating the integrated circuit device 300 shown in FIG. 8 is described with reference to FIGS. 15A to 15D. In FIGS. 15A to 15D, the same reference numerals as in FIGS. 1 to 8 and 11A to 14E respectively denote the same members, and here, repeated descriptions thereof are omitted.

Referring to FIG. 15A, the processes described with reference to FIGS. 11A to 11G and 12A may be performed, followed by performing the processes described with reference to FIGS. 14A and 14B, thereby forming a second conductive barrier metal-containing film 370 and a lower metal plug 372 to fill a lower portion of each of the first and second contact holes H1 and H2 in the first device area I and the second device area II.

Next, in the resulting product of FIG. 14B, an intermediate metal plug 470 may be formed in the first and second contact holes H1 and H2 to cover the second conductive barrier metal-containing film 370 and the lower metal plug 372. After the intermediate metal plug 470 is formed in the first and second contact holes H1 and H2, a portion of each of the first and second contact holes H1 and H2 may remain empty.

In one or more embodiments, to form the intermediate metal plug 470 to fill a portion of each of the first and second contact holes H1 and H2, while the respective upper surfaces of the second conductive barrier metal-containing film 370 and the lower metal plug 372 are exposed in each of the first and second contact holes H1 and H2 as in the resulting product of FIG. 14B, a bottom-up deposition process may be performed such that deposition is performed upward in the vertical direction (the Z direction) from the respective surfaces of the second conductive barrier metal-containing film 370 and the lower metal plug 372 by using the difference between deposition characteristics on the surfaces of second conductive barrier metal-containing film 370 and the lower metal plug 372 and deposition characteristics on the surfaces of the insulating spacer 118 and the capping insulating pattern 168. As such, by using a bottom-up deposition method to form the intermediate metal plug 470, no seam may be formed in the intermediate metal plug 470.

Referring to FIG. 15B, in the resulting product of FIG. 15A, a second major metal plug 474 may be formed to fill a space remaining above the intermediate metal plug 470 in each of the first and second contact holes H1 and H2. In one or more embodiments, to form the second major metal plug 474, an ALD or CVD process may be used.

Referring to FIG. 15C, in the resulting product of FIG. 15B, a mask pattern MP4 may be formed to cover the second device area II, followed by removing the second major metal plug 474, the intermediate metal plug 470, the lower metal plug 372, and the second conductive barrier metal-containing film 370 from the first contact hole H1 in the first device area I by using the mask pattern MP4 as an etch mask, thereby exposing the metal silicide film 172 in the first contact hole H1.

Referring to FIG. 15D, a process of removing the mask pattern MP4, and a process of forming a first conductive barrier metal-containing film 174 and a first major metal plug 376 in the first contact hole H1 in the first device area I may be performed on the resulting product of FIG. 15C. Each of the first conductive barrier metal-containing film 174 and the first major metal plug 376 may be formed by an ALD or CVD process.

To fabricate the integrated circuit device 400A shown in FIG. 9, similar processes to those described with reference to FIGS. 15A to 15D may be performed.

However, in the process described with reference to FIG. 15D, a first major metal plug 376A, instead of the first major metal plug 376, may be formed in the first contact hole H1 in the first device area I. While an ALD or CVD process is being performed to form the first major metal plug 376A, a seam 374S may be formed in the first major metal plug 376A to extend lengthwise in the vertical direction (the Z direction).

To fabricate the integrated circuit device 400B shown in FIG. 10, similar processes to those described with reference to FIGS. 15A to 15D may be performed.

However, in the process described with reference to FIG. 15B, a second major metal plug 474A, instead of the second major metal plug 474, may be formed in the second contact hole H2 in the second device area II, and in the process described with reference to FIG. 15D, a first major metal plug 376A, instead of the first major metal plug 376, may be formed in the first contact hole H1 in the first device area I. While an ALD or CVD process is being performed to form the second major metal plug 474A, a seam 474S may be formed in the second major metal plug 474A to extend lengthwise in the vertical direction (the Z direction). In addition, while an ALD or CVD process is being performed to form the first major metal plug 376A, a seam 374S may be formed in the first major metal plug 376A to extend lengthwise in the vertical direction (the Z direction).

Heretofore, although the examples of the methods of fabricating the integrated circuit devices 100, 100A, 200, 200A, 300, 300A, 400, 400A, and 400B shown in FIGS. 1 to 10 have been described with reference to FIGS. 11A to 15D, it will be understood by those of ordinary skill in the art that, by making various modifications and changes to the examples described with reference to FIGS. 11A to 15D without departing from the spirit and scope of the disclosure, integrated circuit devices having various structures modified and changed therefrom may be fabricated.

Although the disclosure generally relates to a device including a fin field-effect transistor (FinFET) including a channel region of a fin-shaped pattern shape, and a transistor including a nanowire or a nanosheet, the disclosure is not limited thereto. The semiconductor device according to one or more embodiments may include a tunneling transistor (tunneling FET), a three-dimensional (3D) transistor or a vertical field-effect transistor (VFET). The semiconductor device according to one or more embodiments may include a planar transistor. In addition, the technical idea of the present disclosure may be applied to a transistor based on a two-dimensional material (2D material based FETs) and a heterostructure thereof. Further, the semiconductor device according to one or more embodiments may also include a bipolar junction transistor, a laterally diffused metal oxide semiconductor (LDMOS), or the like.

While the disclosure has been particularly shown and described with reference to one or more embodiments thereof, it will be understood that various changes in form and details may be made therein without departing from the spirit and scope of the following claims.

What is claimed is:

1. An integrated circuit device comprising:
a first transistor comprising a first channel region and a first source/drain region connected to the first channel region;
a second transistor comprising a second channel region and a second source/drain region connected to the second channel region;
a first contact structure connected to the first source/drain region; and
a second contact structure connected to the second source/drain region,
wherein each of the first contact structure and the second contact structure comprises at least two metal-containing films,
wherein the first contact structure comprises a first major metal plug having a largest volume among respective volumes of each of the at least two metal-containing films of the first contact structure,
wherein the second contact structure comprises a second major metal plug having a largest volume among respective volumes of each of the at least two metal-containing films of the second contact structure,
wherein the first major metal plug and the second major metal plug respectively comprise different metals, and
wherein a cross-sectional shape of the first major metal plug is different from a cross-sectional shape of the second major metal plug.

2. The integrated circuit device of claim 1,
wherein the first transistor comprises a n-channel metal-oxide semiconductor (NMOS) transistor,
wherein the second transistor comprises a p-channel metal-oxide semiconductor (PMOS) transistor,
wherein the first major metal plug has a U-like cross-sectional shape defining an inner space thereof, and
wherein the second major metal plug has a pillar shape and comprises a metal in a horizontal direction from an outer surface of the second major metal plug to an inner center of the second major metal plug.

3. The integrated circuit device of claim 2, wherein the first contact structure further comprises:
a first minor metal plug in the inner space defined by the first major metal plug, wherein the first minor metal plug is in contact with an inner surface of the first major metal plug, and wherein the first minor metal plug comprises a metal different from a metal of the first major metal plug; and
a first conductive barrier metal-containing film which at least partially surrounds the first major metal plug and the first minor metal plug and is in contact with an outer surface of the first major metal plug.

4. The integrated circuit device of claim 2, wherein the second contact structure further comprises:
a second minor metal plug having a U-like cross-sectional shape and comprising a metal different from a metal of the second major metal plug, wherein the second minor metal plug at least partially surrounds the second major metal plug and is in contact with the outer surface of the second major metal plug; and
a second conductive barrier metal-containing film which at least partially surrounds the second major metal plug and the second minor metal plug and is in contact with an outer surface of the second minor metal plug.

5. The integrated circuit device of claim 1,
wherein the first transistor comprises an n-channel metal-oxide semiconductor (NMOS) transistor,
wherein the second transistor comprises a p-channel metal-oxide semiconductor (PMOS) transistor,
wherein the first major metal plug has a pillar shape and comprises a metal in a horizontal direction from an outer surface of the first major metal plug to an inner center of the first major metal plug, and
wherein the second major metal plug has a U-like cross-sectional shape defining an inner space thereof.

6. The integrated circuit device of claim 5, wherein the first contact structure further comprises:
a first minor metal plug having a U-like cross-sectional shape and comprising a metal different from a metal of the first major metal plug, wherein the first minor metal plug at least partially surrounds the first major metal plug and is in contact with the outer surface of the first major metal plug; and
a first conductive barrier metal-containing film which at least partially surrounds the first major metal plug and the first minor metal plug and is in contact with an outer surface of the first minor metal plug.

7. The integrated circuit device of claim 5, wherein the second contact structure further comprises:
a second minor metal plug in the inner space defined by the second major metal plug, wherein the second minor metal plug is in contact with an inner surface of the second major metal plug, and wherein the second minor metal plug comprises a metal different from a metal of the second major metal plug; and
a second conductive barrier metal-containing film which at least partially surrounds the second major metal plug and the second minor metal plug and is in contact with an outer surface of the second major metal plug.

8. The integrated circuit device of claim 1,
wherein the first transistor comprises an n-channel metal-oxide semiconductor (NMOS) transistor,
wherein the second transistor comprises a p-channel metal-oxide semiconductor (PMOS) transistor,
wherein each of the first major metal plug and the second major metal plug have a pillar shape and comprises a metal in a horizontal direction from an outer surface thereof to an inner center thereof, and
wherein a first length of the first major metal plug in a vertical direction is greater than a second length of the second major metal plug in the vertical direction.

9. The integrated circuit device of claim 8,
wherein the first contact structure further comprises a first conductive barrier metal-containing film which at least partially surrounds the first major metal plug and is in contact with the outer surface of the first major metal plug, and
wherein the second contact structure further comprises:
a second conductive barrier metal-containing film between the second source/drain region and the second major metal plug in the vertical direction, the second conductive barrier metal-containing film comprising an inner surface that is concave toward the second major metal plug; and
a lower metal plug between the second conductive barrier metal-containing film and the second major metal plug, the lower metal plug comprising a convex surface contacting the concave inner surface of the second conductive barrier metal-containing film.

10. The integrated circuit device of claim 9, wherein each of the second conductive barrier metal-containing film and the lower metal plug is in contact with a lower surface of the second major metal plug.

11. The integrated circuit device of claim 9,
wherein the second contact structure further comprises an intermediate metal plug between the second major metal plug and the lower metal plug in the vertical direction,
wherein the intermediate metal plug has a pillar shape and comprises a metal in the horizontal direction from an outer surface of the intermediate metal plug to an inner center of the intermediate metal plug,
wherein each of the second conductive barrier metal-containing film and the lower metal plug are separated from the second major metal plug in the vertical direction with the intermediate metal plug therebetween, and
wherein a lower surface of the second major metal plug is in contact with an upper surface of the intermediate metal plug.

12. The integrated circuit device of claim 9,
wherein the second contact structure further comprises an intermediate metal plug between the second major metal plug and the lower metal plug in the vertical direction,
wherein the intermediate metal plug has a pillar shape and comprises a metal in the horizontal direction from an outer surface of the intermediate metal plug to an inner center of the intermediate metal plug,
wherein the second major metal plug comprises a seam therein, and
wherein the intermediate metal plug does not comprise a seam therein.

13. An integrated circuit device comprising:
a plurality of channel regions each comprising a plurality of nanosheets, the plurality of channel regions comprising a first channel region and a second channel region;
a plurality of gate lines each surrounding a channel region of the plurality of channel regions;
a first source/drain region in contact with the plurality of nanosheets of the first channel region, the first source/drain region comprising a Si layer doped with an n-type dopant;
a first contact structure connected to the first source/drain region;
a second source/drain region in contact with the plurality of nanosheets of the second channel region, the second source/drain region comprising a SiGe layer doped with a p-type dopant; and
a second contact structure connected to the second source/drain region,
wherein each of the first contact structure and the second contact structure comprises at least two metal-containing films,
wherein the first contact structure comprises a first major metal plug having a largest volume among respective volumes of each of the at least two metal-containing films of the first contact structure,
wherein the second contact structure comprises a second major metal plug having a largest volume among respective volumes of each of the at least two metal-containing films of the second contact structure,
wherein the first major metal plug and the second major metal plug respectively comprise different metals, and
wherein a cross-sectional shape of the first major metal plug is different from a cross-sectional shape of the second major metal plug.

14. The integrated circuit device of claim 13,
wherein each of the first contact structure and the second contact structure comprises molybdenum (Mo), copper (Cu), tungsten (W), cobalt (Co), ruthenium (Ru), manganese (Mn), titanium (Ti), tantalum (Ta), aluminum (Al), titanium nitride (TiN), tantalum nitride (TaN), tungsten nitride (WN), tungsten carbonitride (WCN), titanium silicon nitride (TiSiN), tantalum silicon nitride (TaSiN), or tungsten silicon nitride (WSiN), or a combination thereof, and
wherein the first major metal plug and the second major metal plug respectively comprise a different metal selected from molybdenum (Mo), copper (Cu), tungsten (W), cobalt (Co), ruthenium (Ru), manganese (Mn), titanium (Ti), tantalum (Ta), and aluminum (Al).

15. The integrated circuit device of claim 13,
wherein the first major metal plug comprises a metal which induces tensile strain in the plurality of nanosheets of the first channel region, and
wherein the second major metal plug comprises a metal which induces compressive strain in the plurality of nanosheets of the second channel region.

16. The integrated circuit device of claim 13,
wherein the first major metal plug comprises molybdenum (Mo), and
wherein the second major metal plug comprises tungsten (W), cobalt (Co), or a combination thereof.

17. The integrated circuit device of claim 13,
wherein the first major metal plug has a U-like cross-sectional shape defining an inner space thereof,
wherein the first contact structure further comprises:
a first minor metal plug in the inner space defined by the first major metal plug, wherein the first minor metal plug is in contact with an inner surface of the first major metal plug, and wherein the first minor metal plug comprises a metal different from a metal of the first major metal plug; and
a first conductive barrier metal-containing film which at least partially surrounds the first major metal plug and the first minor metal plug and is in contact with an outer surface of the first major metal plug,
wherein the second major metal plug has a pillar shape and comprises a metal in a horizontal direction from an outer surface of the second major metal plug to an inner center of the second major metal plug, and
wherein the second contact structure further comprises:
a second minor metal plug having a U-like cross-sectional shape and comprising a metal different from a metal of the second major metal plug, wherein the second minor metal plug at least partially surrounds the second major metal plug and is in contact with the outer surface of the second major metal plug; and
a second conductive barrier metal-containing film which at least partially surrounds the second major metal plug and the second minor metal plug and is in contact with an outer surface of the second minor metal plug.

18. The integrated circuit device of claim 13,
wherein the first major metal plug has a pillar shape and comprises a metal in a horizontal direction from an outer surface of the first major metal plug to an inner center of the first major metal plug,
wherein the first contact structure further comprises:
a first minor metal plug having a U-like cross-sectional shape and comprising a metal different from a metal of the first major metal plug, wherein the first minor metal plug at least partially surrounds the first major metal plug and is in contact with the outer surface of the first major metal plug; and
a first conductive barrier metal-containing film which at least partially surrounds the first major metal plug and the first minor metal plug and is in contact with an outer surface of the first minor metal plug,
wherein the second major metal plug has a U-like cross-sectional shape defining an inner space thereof, and
wherein the second contact structure further comprises:
a second minor metal plug in the inner space defined by the second major metal plug, wherein the second minor metal plug is in contact with an inner surface of the second major metal plug, and wherein the second minor metal plug comprises a metal different from a metal of the second major metal plug; and
a second conductive barrier metal-containing film which at least partially surrounds the second major metal plug and the second minor metal plug and is in contact with an outer surface of the second major metal plug.

19. The integrated circuit device of claim 13,
wherein each of the first major metal plug and the second major metal plug has a pillar shape and comprises a metal in a horizontal direction from an outer surface thereof to an inner center thereof, and
wherein a first length of the first major metal plug in a vertical direction is greater than a second length of the second major metal plug in the vertical direction.

20. An integrated circuit device comprising:
a plurality of channel regions each comprising a plurality of nanosheets, the plurality of channel regions comprising a first channel region and a second channel region;
an n-channel metal-oxide semiconductor (NMOS) transistor comprising:
the first channel region;
a first gate line surrounding the plurality of nanosheets of the first channel region; and
a first source/drain region in contact with the plurality of nanosheets of the first channel region, the first source/drain region comprising a Si layer doped with an n-type dopant;
a p-channel metal-oxide semiconductor (PMOS) transistor comprising:
the second channel region;
a second gate line surrounding the plurality of nanosheets of the second channel region; and
a second source/drain region in contact with the plurality of nanosheets of the second channel region, the second source/drain region comprising a SiGe layer doped with a p-type dopant;
a first contact structure connected to the first source/drain region; and
a second contact structure connected to the second source/drain region,
wherein each of the first contact structure and the second contact structure comprises at least two metal-containing films,
wherein the first contact structure comprises a first major metal plug having a largest volume among respective volumes of the at least two metal-containing films of the first contact structure,
wherein the second contact structure comprises a second major metal plug having a largest volume among respective volumes of the at least two metal-containing films of the second contact structure,
wherein the first major metal plug and the second major metal plug respectively comprise different metals selected from molybdenum (Mo), copper (Cu), tungsten (W), cobalt (Co), ruthenium (Ru), manganese (Mn), titanium (Ti), tantalum (Ta), and aluminum (Al), and
wherein a cross-sectional shape of the first major metal plug is different from a cross-sectional shape of the second major metal plug.
